(19) United States
(12) Patent Application Publication
(10) Pub. No.: US 2019/0157470 A1
(43) Pub. Date: May 23, 2019

(54) DETECTOR FOR OPTICALLY DETECTING AT LEAST ONE OBJECT

(71) Applicant: trinamiX GmbH, Ludwigshafen am Rhein (DE)

(72) Inventors: Robert SEND, Ludwigshafen (DE); Ingmar BRUDER, Ludwigshafen (DE); Christoph LUNGENSCHMIED, Ludwigshafen (DE); Wilfried HERMES, Ludwigshafen (DE); Sebastian VALOUCH, Ludwigshafen (DE)

(73) Assignee: trinamiX GmbH, Ludwigshafen am Rhein (DE)

(21) Appl. No.: 16/091,409

(22) PCT Filed: Apr. 3, 2017
(86) PCT No.: PCT/EP2017/057867

§ 371 Date: Oct. 4, 2018

(30) Foreign Application Priority Data
Apr. 6, 2016 (EP) 16164114.7
May 24, 2016 (EP) 16171049.6

(51) Int. Cl. H01L 31/02; G01S 17/46; G01S 7/481; H01L 31/101; H01L 31/105; H01L 27/146

(52) U.S. Cl. CPC H01L 31/02024; G01S 17/46; G01S 7/4814; H01L 27/14665; H01L 31/1016; H01L 31/1055; G01S 7/4816

(57) ABSTRACT

A detector for determining a position of at least one object, in particular for 3D-sensing concepts, is disclosed. The detector comprises a longitudinal optical sensor (110) for determining a longitudinal position of an object by a light beam traveling from the object to the detector and a transversal optical detector (112) which may be designed as an imaging device or a position sensitive detector. The longitudinal sensor (110) has at least two PN structures or PIN structures (138, 140). Each of the PN structures or PIN structures is located between two electrode layers (144), thereby forming photodiodes (146) having a longitudinal sensor region (148) each. Longitudinal sensor signals from the photodiodes (146) are, given the same total power of illumination, are dependent on a beam cross-section of the light beam in the longitudinal sensor regions (148). As an alternative, instead of the transversal optical detector (112) the photodiodes (146) of the longitudinal optical sensor (110) may be adapted to operate as one-dimensional position sensitive detectors each, for determining a transversal x-coordinate and a transversal y-coordinate, respectively.

### FIELD OF THE INVENTION

The invention relates to a detector, a detector system and a method for determining a position of at least one object. The invention further relates to a human-machine interface for exchanging at least one item of information between a user and a machine, an entertainment device, a tracking system, a camera, a scanning system, a method and various uses of the detector device. The devices, systems and uses according to the present invention specifically may be employed for example in various areas of daily life, gaming, traffic technology, production technology, security technology, photography such as digital photography or video photography for arts, documentation or technical purposes, medical technology or in the sciences. However, other applications are also possible.

### PRIOR ART

A large number of optical sensors and photovoltaic devices are known from the prior art. While photovoltaic devices are generally used to convert electromagnetic radiation, for example, ultraviolet, visible or infrared light, into electrical signals or electrical energy, optical detectors are generally used for picking up image information and/or for detecting at least one optical parameter, for example, a brightness.

A large number of optical sensors which can be based generally on the use of inorganic and/or organic sensor materials are known from the prior art. Examples of such sensors are disclosed in US 2007/0176165 A1, U.S. Pat. No. 6,995,445 B2, DE 2501124 A1, DE 3225372 A1 or else in numerous other prior art documents. To an increasing extent, in particular for cost reasons and for reasons of large-area processing, sensors comprising at least one organic sensor material are being used, as described for example in US 2007/0176165 A1. In particular, so-called dye solar cells are increasingly of importance here, which are described generally, for example in WO 2009/013282 A1. The present invention, however, is not restricted to the use of organic devices. Thus, specifically, also inorganic devices such as CCD sensors and/or CMOS sensors, specifically pixelated sensors, may be employed.

A large number of detectors for detecting at least one object are known on the basis of such optical sensors. Such detectors can be embodied in diverse ways, depending on the respective purpose of use. Examples of such detectors are imaging devices, for example, cameras and/or microscopes. High-resolution confocal microscopes are known, for example, which can be used in particular in the field of medical technology and biology in order to examine biological samples with high optical resolution. Further examples of detectors for optically detecting at least one object are distance measuring devices based, for example, on propagation time methods of corresponding optical signals, for example laser pulses. Further examples of detectors for optically detecting objects are triangulation systems, by means of which distance measurements can likewise be carried out.

In WO 2012/110924 A1, the content of which is herewith included by reference, a detector for optically detecting at least one object is proposed. The detector comprises at least one longitudinal optical sensor. The longitudinal optical sensor has at least one sensor region. The longitudinal optical sensor is designed to generate at least one longitudinal sensor signal in a manner dependent on an illumination of the sensor region. The longitudinal sensor signal, given the same total power of the illumination, is dependent on a geometry of the illumination, in particular on a beam cross section of the illumination on the longitudinal sensitive area. The detector furthermore has at least one evaluation device. The evaluation device is designed to generate at least one item of geometrical information from the longitudinal sensor signal, in particular at least one item of geometrical information about the illumination and/or the object.

WO 2014/097181 A1, the full content of which is herewith included by reference, discloses a method and a detector for determining a position of at least one object, by using at least one longitudinal optical sensor and at least one transversal optical sensor. Specifically, the use of sensor stacks is disclosed, in order to determine both a longitudinal position and at least one transversal position of the object with a high degree of accuracy and without ambiguity.

WO 2015/024871 A1, the full content of which is herewith included by reference, discloses an optical detector, comprising:
at least one spatial light modulator being adapted to modify at least one property of a light beam in a spatially resolved fashion, having a matrix of pixels, each pixel being controllable to individually modify the at least one optical property of a portion of the light beam passing the pixel;
at least one optical sensor adapted to detect the light beam after passing the matrix of pixels of the spatial light modulator and to generate at least one sensor signal;
at least one modulator device adapted for periodically controlling at least two of the pixels with different modulation frequencies; and
at least one evaluation device adapted for performing a frequency analysis in order to determine signal components of the sensor signal for the modulation frequencies.

WO 2014/198629 A1, the full content of which is herewith included by reference, discloses a detector for determining a position of at least one object, comprising:
at least one optical sensor, the optical sensor being adapted to detect a light beam propagating from the object towards the detector, the optical sensor having at least one matrix of pixels; and
at least one evaluation device, the evaluation device being adapted to determine a number N of pixels of the optical sensor which are illuminated by the light beam, the evaluation device further being adapted to determine at least one longitudinal coordinate of the object by using the number N of pixels which are illuminated by the light beam.

Further, generally, for various other detector concepts, reference may be made to WO 2014/198626 A1, WO 2014/198629 A1 and WO 2014/198625 A1, the full content of which is herewith included by reference. Further, referring to potential materials and optical sensors which may also be employed in the context of the present invention, reference may be made to European patent applications EP 15 153 215.7, filed on Jan. 30, 2015, EP 15 157 363.1, filed on Mar. 3, 2015, EP 15 164 653.6, filed on Apr. 22, 2015, EP 15177275.3, filed on Jul. 17, 2015, EP 15180354.1 and EP 15180353.3, both filed on Aug. 10, 2015, and EP 15 185 005.4, filed on Sep. 14, 2015, the full content of all of which is herewith also included by reference.

Despite the advantages implied by the above-mentioned devices and detectors, several technical challenges remain. Thus, generally, a need exists for detectors for detecting a position of an object in space which is both reliable and may be manufactured at low cost. Specifically, a need exists for 3D-sensing concepts. Various known concepts are at least partially based on using so-called FiP sensors, such as several of the above-mentioned concepts. Therein, as an example, large area sensors may be used, in which the individual sensor pixels are significantly larger than the light spot and which are fixed to a specific size. Still, large area sensors in many cases are inherently limited in the use of the FiP measurement principle, specifically in case more than one light spot is to be investigated simultaneously.

Further, 3D-sensing concepts for tracking, using FiP sensors, typically require combining one or more FiP sensors and, optionally, a position-sensitive detector (PSD or PIF). FiP sensors and PSD devices are typically either combined electrically, such as in a dye-sensitized solar cell, or are separated into a FiP-detector and a PSD. FiP sensors and the PSD may be arranged such that light of a light beam is splitted, e.g. by a beam splitter, and impinges both the FiP sensors and the PSD. Thus, an expensive beam splitter is necessary. Alternatively, FiP sensors and PSD may be arranged stacked behind each other. For optical systems, it is typically desirable to design at least one of the detectors in a semitransparent fashion. Semitransparency, however, restricts the options of choice for both FiP-detectors and PSD materials. Thus, transparency of FiP and/or PSD detectors remains a technical challenge.

International application PCT/EP2016/051817, filed on Jan. 28, 2016, the full content of which is herewith included by reference, discloses a detector for determining a position of at least one object. The detector may comprise at least two longitudinal optical sensors preferably arranged in form of a stack along an optical axis of the detector, wherein each longitudinal optical sensor may be adapted to generate at least one longitudinal sensor signal. The sensor regions or the sensor surfaces of the longitudinal optical sensors may be oriented in parallel.

However, in such an arrangement of FiP sensor deviations from a common optical axis of the stack may occur, such as angular tolerances. Thus, time-consuming alignment and calibration may be necessary.

Further, pixelated optical sensors may be used, such as in the pixel counting concepts disclosed in WO 2014/198629 A1. Even though these concepts allow for an efficient determination of 3D coordinates and even though these concepts are significantly superior to known 3D sensing concepts such as triangulation, some challenges remain, specifically regarding the need for calculating power and resources, as well as increasing the efficiency. Generally, it might also be desirable to employ commonly available transversal optical sensors, such as CCD and/or CMOS sensors and/or photodiodes such as inorganic photodiodes or organic photodiodes.

In European patent applications EP 15 196 238.8, filed on Nov. 25, 2015, the full content of all of which is herewith also included by reference, discloses a detector for determining a position of a least one object, the detector comprising:
at least one longitudinal optical sensor for determining a longitudinal position of at least one light beam traveling from the object to the detector;
at least one transversal optical sensor for determining at least one transversal position of the at least one light beam traveling from the object to the detector, comprising at least one fluorescent waveguiding sheet forming a transversal sensitive area, wherein the fluorescent waveguiding sheet is oriented towards the object such that the at least one light beam propagating from the object towards the detector generates at least one light spot in the transversal sensitive area, wherein the fluorescent waveguiding sheet contains at least one fluorescent material, wherein the fluorescent material is adapted to generate fluorescence light in response to the illumination by the light beam, and at least two photosensitive elements located at at least two edges of the fluorescent waveguiding sheet capable of detecting fluorescence light guided from the light spot towards the photosensitive elements by the fluorescent waveguiding sheet and capable of generating transversal sensor signals; and
at least one evaluation device.

This discussion of known concepts, such as the concepts of several of the above-mentioned prior art documents, clearly shows that some technical challenges remain. Specifically, there is further room for improvement in terms of increased accuracy of position detectors for distance measurements, two-dimensional sensing or even three-dimensional sensing. Further, complexity of the optical systems still remains an issue which may be addressed.

### Problem Addressed by the Invention

It is therefore an object of the present invention to provide devices and methods facing the above-mentioned technical challenges of known devices and methods. Specifically, it is an object of the present invention to provide devices and methods which reliably may determine a position of an object in space, preferably with a low technical effort and with low requirements in terms of technical resources and cost.

### SUMMARY OF THE INVENTION

This problem is solved by the invention with the features of the independent patent claims. Advantageous developments of the invention, which can be realized individually or in combination, are presented in the dependent claims and/or in the following specification and detailed embodiments.

As used in the following, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may both refer to a situation in which, besides B, no other element is present in A (i.e. a situation in which A solely and exclusively consists of B) and to a situation in which, besides B, one or more further elements are present in entity A, such as element C, elements C and D or even further elements.

Further, it shall be noted that the terms “at least one”, “one or more” or similar expressions indicating that a feature or element may be present once or more than once typically will be used only once when introducing the respective feature or element. In the following, in most cases, when referring to the respective feature or element, the expressions “at least one” or “one or more” will not be repeated, non-withstanding the fact that the respective feature or element may be present once or more than once.

Further, as used in the following, the terms “preferably”, “more preferably”, “particularly”, “more particularly”, “specifically”, “more specifically” or similar terms are used in conjunction with optional features, without restricting alternative possibilities. Thus, features introduced by these terms are optional features and are not intended to restrict the scope of the claims in any way. The invention may, as the skilled person will recognize, be performed by using alternative features. Similarly, features introduced by “in an embodiment of the invention” or similar expressions are intended to be optional features, without any restriction regarding alternative embodiments of the invention, without any restrictions regarding the scope of the invention and without any restriction regarding the possibility of combining the features introduced in such a way with other optional or non-optional features of the invention.

In a first aspect of the present invention, a detector for determining a position of at least one object is disclosed.

The “object” generally may be an arbitrary object, chosen from a living object and a non-living object. Thus, as an example, the at least one object may comprise one or more articles and/or one or more parts of an article. Additionally or alternatively, the object may be or may comprise one or more living beings and/or one or more parts thereof, such as one or more body parts of a human being, e.g. a user, and/or an animal.

As used herein, the term “position” refers to at least one item of information regarding a location and/or orientation of the object and/or at least one part of the object in space. Thus, the at least one item of information may imply at least one distance between at least one point of the object and the at least one detector. As will be outlined in further detail below, the distance may be a longitudinal coordinate or may contribute to determining a longitudinal coordinate of the point of the object. Additionally or alternatively, one or more other items of information regarding the location and/or orientation of the object and/or at least one part of the object may be determined. As an example, at least one transversal coordinate of the object and/or at least one part of the object may be determined. Thus, the position of the object may imply at least one longitudinal coordinate of the object and/or at least one part of the object. Additionally or alternatively, the position of the object may imply at least one transversal coordinate of the object and/or at least one part of the object. Additionally or alternatively, the position of the object may imply at least one orientation information of the object, indicating an orientation of the object in space.

Thus, as an example, the detector may constitute a coordinate system in which the optical axis forms the z-axis and in which, additionally, an x-axis and a y-axis may be provided which are perpendicular to the z-axis and which are perpendicular to each other. As an example, the detector and/or a part of the detector may rest at a specific point in this coordinate system, such as at the origin of this coordinate system. In this coordinate system, a direction parallel or antiparallel to the z-axis may be regarded as a longitudinal direction, and a coordinate along the z-axis may be considered a longitudinal coordinate. An arbitrary direction perpendicular to the longitudinal direction may be considered a transversal direction, and an x- and/or y-coordinate may be considered a transversal coordinate.

Alternatively, other types of coordinate systems may be used. Thus, as an example, a polar coordinate system may be used in which the optical axis forms a z-axis and in which a distance from the z-axis and a polar angle may be used as additional coordinates. Again, a direction parallel or antiparallel to the z-axis may be considered a longitudinal direction, and a coordinate along the z-axis may be considered a longitudinal coordinate. Any direction perpendicular to the z-axis may be considered a transversal direction, and the polar coordinate and/or the polar angle may be considered a transversal coordinate.

As used herein, the detector for optical detection generally is a device which is adapted for providing at least one item of information on the position of the at least one object. The detector may be a stationary device or a mobile device. Further, the detector may be a stand-alone device or may form part of another device, such as a computer, a vehicle or any other device. Further, the detector may be a hand-held device. Other embodiments of the detector are feasible.

The detector may be adapted to provide the at least one item of information on the position of the at least one object in any feasible way. Thus, the information may e.g. be provided electronically, visually, acoustically or in any arbitrary combination thereof. The information may further be stored in a data storage of the detector or a separate device and/or may be provided via at least one interface, such as a wireless interface and/or a wire-bound interface.

The detector comprises:
at least one longitudinal optical sensor for determining a longitudinal position of at least one light beam traveling from the object to the detector, the longitudinal optical sensor having a layer setup, wherein the longitudinal optical sensor comprises at least two p-type semiconductor layers, at least two n-type semiconductor layers, and at least three individual electrode layers, wherein the p-type semiconductor layers and the n-type semiconductor layers form at least two individual PN structures, wherein each of the PN structures is located between at least two of the electrode layers, thereby forming at least two photodiodes,
wherein each of the two photodiodes has at least one longitudinal sensor region, wherein the longitudinal optical sensor is designed to generate at least two longitudinal sensor signals in a manner dependent on an illumination of the longitudinal sensor region by the light beam, wherein the longitudinal sensor signals, given the same total power of the illumination, are dependent on a beam cross-section of the light beam in the longitudinal sensor region; and
at least one evaluation device, wherein the evaluation device is configured to determine at least one longitudinal coordinate of the object by evaluating the longitudinal sensor signals.

Herein, the components listed above may be separate components. Alternatively, two or more of the components as listed above may be integrated into one component. Further, the at least one evaluation device may be formed as a separate evaluation device independent from the transfer device and the longitudinal optical sensors, but may preferably be connected to the longitudinal optical sensors in order to receive the longitudinal sensor signal. Alternatively, the at least one evaluation device may fully or partially be integrated into the longitudinal optical sensors.

As used herein, the “longitudinal optical sensor” is generally a device which is designed to generate at least one longitudinal sensor signal in a manner dependent on an illumination of the sensor region by the light beam, wherein the longitudinal sensor signal, given the same total power of the illumination, is dependent, according to the so-called “FiP effect” on a beam cross-section of the light beam in the sensor region.

As used herein, a “sensor signal” generally refers to an arbitrary memorable and transferable signal which is generated by the longitudinal optical sensor and/or the transversal optical sensor, in particular, by the photodiodes, in response to the illumination. Thus, as an example, the sensor signal may be or may comprise at least one electronic signal, which may be or may comprise a digital electronic signal and/or an analogue electronic signal. The sensor signal may be or may comprise at least one voltage signal and/or at least one current signal. Further, either raw sensor signals may be used, or the detector, the optical sensor or any other element may be adapted to process or preprocess the sensor signal, thereby generating secondary sensor signals, which may also be used as sensor signals, such as preprocessing by filtering or the like.

The longitudinal sensor signal may generally be an arbitrary signal indicative of the longitudinal position, which may also be denoted as a depth. As an example, the longitudinal sensor signal may be or may comprise a digital and/or an analog signal. As an example, the longitudinal sensor signal may be or may comprise a voltage signal and/or a current signal. Additionally or alternatively, the longitudinal sensor signal may be or may comprise digital data. The longitudinal sensor signal may comprise a single signal value and/or a series of signal values. The longitudinal sensor signal may further comprise an arbitrary signal which is derived by combining two or more individual signals, such as by averaging two or more signals and/or by forming a quotient of two or more signals. For potential embodiments of the longitudinal optical sensor and the longitudinal sensor signal, reference may be made to the optical sensor as disclosed in WO 2012/110924 A1

Unless explicitly specified, the term “optical sensor” as used herein or any part thereof, such as a sensitive region, or any feature related thereto, such as a sensor signal, may refer to one or to both of a longitudinal optical sensor and a transversal optical sensor. In accordance with the present invention, the longitudinal optical sensor is used for determining a longitudinal position of at least one light beam traveling from the object to the detector and, by employing the evaluation device, for determining at least one longitudinal coordinate z of the object whereas the transversal optical sensor is used for determining a transversal position of the at least one light beam traveling from the object to the detector and, by employing the evaluation device for evaluating the transversal sensor signals, for determining at least one of the transversal coordinates x, y of the object. Herein, the transversal optical sensor may, preferably, be configured in order to function as a “position sensitive detector” (PSD) by being capable of providing both of the two lateral components of the spatial position of the object, in particular, simultaneously. As a result, by combining the at least one longitudinal coordinate of the object with the at least one transversal coordinate of the object a three-dimensional position of the object as defined above may, thus, be determined by using the evaluation device.

As used herein, an optical sensor generally refers to a light-sensitive device for detecting a light beam, such as for detecting an illumination and/or a light spot generated by a light beam. As further used herein, a light spot generally refers to a visible or detectable round or non-round illumination of an object by a light beam. In the light spot, the light may fully or partially be scattered or may simply be transmitted. The optical sensor may be adapted, as outlined in further detail below, to determine at least one longitudinal coordinate of the object and/or of at least one part of the object, such as at least one part of the object from which the at least one light beam travels towards the detector.

As used herein, the term “sensor region” generally refers to a two-dimensional or three-dimensional region which preferably, but not necessarily, is continuous and can form a continuous region, wherein the sensor region is designed to vary at least one measurable property, in a manner dependent on the illumination. By way of example, said at least one property can comprise an electrical property, for example, by the sensor region being designed to generate, solely or in interaction with other elements of the optical sensor, a photovoltage and/or a photocurrent and/or some other type of signal. In particular the sensor region can be embodied in such a way that it generates a uniform, preferably a single, signal in a manner dependent on the illumination of the sensor region. The sensor region can thus be the smallest unit of the longitudinal optical sensor for which a uniform signal, for example, an electrical signal, is generated, which preferably can no longer be subdivided to partial signals, for example for partial regions of the sensor region. The longitudinal optical sensor can have one or else a plurality of such sensor regions, the latter case for example by a plurality of such sensor regions being arranged in a two-dimensional and/or three-dimensional matrix arrangement.

The term “light beam” generally refers to an amount of light emitted into a specific direction. Thus, the light beam may be a bundle of the light rays having a predetermined extension in a direction perpendicular to a direction of propagation of the light beam. Preferably, the light beam may be or may comprise one or more Gaussian light beams which may be characterized by one or more Gaussian beam parameters, such as one or more of a beam waist, a Rayleigh-length or any other beam parameter or combination of beam parameters suited to characterize a development of a beam diameter and/or a beam propagation in space.

The light beam might be admitted by the object itself, i.e. might originate from the object. Additionally or alternatively, another origin of the light beam is feasible. Thus, as will be outlined in further detail below, one or more illumination sources might be provided which illuminate the object, such as by using one or more primary rays or beams, such as one or more primary rays or beams having a predetermined characteristic. In the latter case, the light beam propagating from the object to the detector might be a light beam which is reflected by the object and/or a reflection device connected to the object.

The longitudinal optical sensor and the method proposed in the context of the present invention, specifically, may be considered as implementing the so-called “FiP” effect which is explained in further detail in WO 2012/110924 A1 and/or in WO 2014/097181 A1. Therein, “FiP” alludes to the effect that a signal i may be generated which, given the same total power P of the illumination, depends on the photon density, the photon flux and, thus, on the cross-section ϕ (F) of the incident beam. Consequently, determining the longitudinal coordinate may imply directly determining the longitudinal coordinate z, may imply determining one or more parameters defining the size of the light spot or may imply both, simultaneously or in a stepwise fashion.

Further, the FiP-effect may depend on or may be emphasized by an appropriate modulation of the light beam, as disclosed in WO 2012/110924 A1. Thus, preferably, the detector may furthermore have at least one modulation device for modulating the illumination. Accordingly, the detector may be designed to detect at least two longitudinal sensor signals in case of different modulations, in particular at least two longitudinal sensor signals comprising different modulation frequencies. In this case, the evaluation device may be configured to determine the at least one longitudinal coordinate of the object by evaluating the at least two modulated longitudinal sensor signals. Thus, the longitudinal optical sensor may be designed in such a way that the at least one longitudinal sensor signal, given the same total power of the illumination, may be dependent on a modulation frequency of a modulation of the illumination. Further, the detector may, alternatively or, preferably, additionally, be designed to detect at least two transversal sensor signals in case of different modulations, in particular at least two transversal sensor signals comprising different modulation frequencies. In this case, the evaluation device may further be configured to determine the at least one transversal coordinate of the object by evaluating the at least two modulated transversal sensor signals. Thus, the transversal optical sensor may be designed in such a way that the at least one transversal sensor signal may also be dependent on a modulation frequency of a modulation of the illumination.

As outlined above, the at least one longitudinal sensor signal, given the same total power of the illumination by the light beam, is, according to the FiP effect, dependent on a beam cross-section of the light beam in the sensor region of the at least one longitudinal optical sensor. As used herein, the term “beam cross-section” generally refers to a lateral extension of the light beam or a light spot generated by the light beam at a specific location. In case a circular light spot is generated, a radius, a diameter or a Gaussian beam waist or twice the Gaussian beam waist may function as a measure of the beam cross-section. In case non-circular light-spots are generated, the cross-section may be determined in any other feasible way, such as by determining the cross-section of a circle having the same area as the non-circular light spot, which is also referred to as the equivalent beam cross-section. Within this regard, it may be possible to employ the observation of an extremum, i.e. a maximum or a minimum, of the longitudinal sensor signal, in particular a global extremum, under a condition in which the corresponding material, such as a photovoltaic material, may be impinged by a light beam with the smallest possible cross-section, such as when the material may be located at or near a focal point as affected by an optical lens. In case the extremum is a maximum, this observation may be denominated as the positive FiP-effect, while in case the extremum is a minimum, this observation may be denominated as the negative FiP-effect.

The term “layer setup” generally refers to an arrangement comprising a multiplicity of layers. The layers may be arranged one on the other. In particular, the layer setup may be manufactured by applying each layer on top of another layer, e.g. sequentially. For example, layers may be applied by a deposition method, preferably a coating method. The layer setup may be monolithic. The longitudinal optical sensor comprises at least two p-type semiconductor layers, at least two n-type semiconductor layers, and at least three individual electrode layers. The p-type semiconductor layers and the n-type semiconductor layers form at least two individual PN structures, wherein each of the PN structures is located between at least two of the electrode layers, thereby forming at least two photodiodes. The PN structures may be separated by at least one electrode layer. The longitudinal optical sensor may comprise a multiplicity n of PN structures. Each of the PN structures may be located between at least two electrode layers, such that, in this embodiment, the longitudinal optical sensor may comprise at least n+1 electrode layers. As generally used, the term “PN structure” refers to an electronic device which comprises an n-type semiconductor layer and a p-type semiconductor layer and which is based upon a p-n junction. As known from the state of the art, while in the n-type semiconductor layer charge carriers are predominantly provided by electrons, in the p-type semiconductor layer the charge carriers are predominantly provided by holes. The p-type semiconductor layers and the n-type semiconductor layers may comprise cadmium telluride (CdTe). As used herein, the “photodiode” refers to a known electronic element which comprises an electrically conducting material, in particular a semiconducting material, which exhibits a pn-junction or a PIN structure, i.e. at least two types of the material inside the photodiode, wherein the at least two types of materials comprises a different kind of doping, being denominated as “p-type” and “n-type” material, which may, further, be separated by an intrinsic “i”-type region.

The longitudinal optical sensor may comprise at least two intrinsic semiconductor layers. The intrinsic semiconductor layer is also denoted as i-type semiconductor layer in the following. Each of the intrinsic semiconductor layers may be located between one of the p-type semiconductor layers and one of the n-type semiconductor layers, thereby forming at least two individual PIN structures. Each of the PIN structures may be located between at least two of the electrode layers, thereby forming at least two photodiodes, in particular a PIN-diode. The longitudinal optical sensor may comprise a multiplicity n of PIN structures. Each of the PIN structures may be located between at least two electrode layers, such that, in this embodiment, the longitudinal optical sensor may comprise at least n+1 electrode layers.

The longitudinal optical sensor may comprise at least one intrinsic semiconductor layer. The intrinsic semiconductor layer may be located between one of the p-type semiconductor layers and one of the n-type semiconductor layers, thereby forming at least one PIN structure. The longitudinal optical sensor may comprise at least one PIN structure and at least one PN structure. The PIN structure and the PN structure may be located between at least two of the electrode layers, thereby forming at least two photodiodes, in particular a PIN-diode and a PN-diode.

As generally used, the term “PIN structure” refers to an electronic device which comprises an intrinsic semiconductor layer (i-type semiconductor layer) that is located between an n-type semiconductor layer and a p-type semiconductor layer. As known from the state of the art, while in the n-type semiconductor layer charge carriers are predominantly provided by electrons, in the p-type semiconductor layer the charge carriers are predominantly provided by holes. Alternatively, the terms “nip diode”, “NIP diode”, or “n-i-p diode” may also be used here. As a further alternative, the term “bulk heterojunction” may also be used, in particular, in case organic materials are involved.

The PIN structure can be arranged in form of a thin-film solar cell. In particular, the p-type semiconductor layer as being used for the purposes of the present invention may exhibit a diamond-like structure, thus, comprising a number of tetravalent atoms. As a result, the p-type semiconductor layer may be selected from one or more of diamond (C), silicon (Si), silicon carbide (SIC), silicon germanium (SiGe), or germanium (Ge). Alternatively, the p-type semiconductor layer may exhibit a modified diamond-like structure, wherein one or more of the tetravalent atoms of the diamond-like structure may be substituted by an atom combination which may, in particular, affect an average of four valence electrons within the modified structure. As an example, a III-V compound comprising one chemical element from each of the groups III and V of the periodic table may be suitable for this purpose since two tetravalent atoms which jointly comprise 2×4=8 valence electrons may, accordingly, be replaced by 3+5=8 valence electrons. As a further example, a I-III-VI₂ compound comprising one chemical element from each of the groups I and III and two chemical elements from the group VI may also be used since four tetravalent atoms jointly comprising 4×4=16 valence electrons may, here, be replaced by 1+4+(2×6)=16 valence electrons. However, other kinds of combinations may also be feasible.

Thus, the p-type semiconductor layer may, preferably, be selected from the group comprising
a III-V compound, in particular indium antimonide (InSb), gallium nitride (GaN), gallium arsenide (GaAs), indium gallium arsenide (InGaAs), or aluminum gallium phosphide (AlGaP);
a II-VI compound, in particular cadmium telluride (CdTe), or mercury cadmium telluride (HgCdTe, also abbreviated to “MCT”) which may be considered as II-VI ternary alloy of CdTe and HgTe;
a I-III-VI₂ compound, in particular copper indium sulfide (CuInS₂; CIS) and, more preferred, copper indium gallium selenide (CIGS) which may be considered as a solid solution of copper indium selenide (CIS) and copper gallium selenide (CuGaSe₂), thus, comprising a chemical formula of CuInₓGa₍₁₋ₓ₎Se₂, wherein x can vary from 0, i.e. pure CuGaSe₂, to 1, i.e. pure CIS;
a I₂-II-IV-VI₄ compound, in particular copper zinc tin sulfide (CZTS), copper zinc tin selenide (CZTSe), or a copper-zinc-tin sulfur-selenium chalcogenide (CZTSSe); and
a halide perovskite compound, especially a compound comprising an alkaline cation, or, in particular, an organic-inorganic halide perovskite, such as a methylammonium metal halide (CH₃NH₃MX₃ with M being a divalent metal, such as Pb or Sn, and X═Cl, Br, or I), preferably methylammonium lead iodide (CH₃NH₃PbI₃).

Hereby, compounds, such as CZTS, which neither comprise rare chemical elements, such as Indium (In), nor toxic chemical elements, such as cadmium (Cd), may especially be preferred. However, further types of compounds and/or additional examples may also be feasible.

In addition, further considerations may, however, concern a sensitivity of the addressed p-type semiconductor layer with particular respect to an absorption rate as a function of the wavelength of the incident light beam. Within this respect, the mentioned I-III-V₂ compounds CIS and CIGS as well as the mentioned I₂-II-IV-VI₄ compounds CZTS, CZTSe, and CZTSSe may particularly be used for related purposes within both the visual spectral range and the NIR spectral range from 780 nm to 1300 nm. For longer wavelengths, in particular above 1300 nm, the II-VI compounds InSb and HgCdTe (MCT) can, however, be a preferred choice.

Further, the n-type semiconductor layer within this type of thin-film solar cell may, preferably, comprise cadmium sulfide (CdS) or, in particular, for avoiding toxic cadmium (Cd) one or more of zinc sulfide (ZnS), zinc oxide (ZnO), or zinc hydroxide (ZnOH).

One or more of the intrinsic semiconductor layers, the p-type semiconductor layers and the n-type semiconductor layers may comprise one or more of amorphous silicon, also abbreviated as “a-Si”, an alloy comprising amorphous silicon, microcrystalline silicon, or cadmium telluride (CdTe). The alloy comprising amorphous silicon may be an amorphous alloy comprising silicon and carbon or an amorphous alloy comprising silicon and germanium. As generally used, the term “amorphous silicon” relates to a non-crystalline allotropic form of silicon. As further known from the state of the art, the amorphous silicon can be obtained by depositing it as a layer, especially as a thin film, onto an appropriate substrate. However, other methods may be applicable.

Further, the amorphous silicon may be passivated by using hydrogen, by which application a number of dangling bonds within the amorphous silicon may be reduced by several orders of magnitude. As a result, hydrogenated amorphous silicon, usually abbreviated to “a-Si:H”, may exhibit a low amount of defects, thus, allow using it for optical devices. In a preferred embodiment, the p-type semiconductor layer, the intrinsic semiconductor layer and the n-type semiconductor layer may be based on a-Si:H. The thickness of the intrinsic semiconductor layer may be from 100 nm to 300 nm, in particular from 150 nm to 200 nm.

Photovoltaic diodes which are provided in the form of a PIN-diode comprising amorphous silicon are, generally, known to exhibit a non-linear frequency response. As a result, the positive and/or the negative FiP effect may be observable in the longitudinal sensor which may, moreover, be substantially frequency-independent in a range of a modulation frequency of the light beam of 0 Hz to 50 kHz. Experimental results which demonstrate an occurrence of the mentioned features will be presented below in more detail. Further, the optical detector comprising the amorphous silicon may exhibits the particular advantages of abundance of the respective semiconductor material, of an easy production route, and of a considerably high signal-to-noise ratio compared to other known FiP devices.

Further, taking into account a behavior of an external quantum efficiency of the PIN diode vs. the wavelength of the incident beam may provide insight into a wavelength range of the incident beam for which the PIN diode may particularly be suitable. Herein, the term “external quantum efficiency” refers to a fraction of photon flux which may contribute to the photocurrent in the present sensor. As a result, the PIN diode which comprises the amorphous silicon may exhibit a particularly high value for the external quantum efficiency within the wavelength range which may extend from 380 nm to 700 nm whereas the external quantum efficiency may be lower for wavelengths outside this range, in particular for wavelengths below 380 nm, i.e. within the UV range, and for wavelengths above 700 nm, in particular within the NIR range, thereby being vanishingly small above 800 nm. Consequently, the PIN diode which the amorphous silicon in at least one of the semiconductor layers may preferably be employed in the detector according to the present invention for the optical detection of the at least one object when the incident beam has a wavelength within a range which covers most of the visual spectral range, especially from 380 nm to 700 nm.

Alternatively, a further PIN diode may be provided which could preferably be employed in the detector according to the present invention when the incident beam may have a wavelength within the UV spectral range. As used herein, the term “UV spectral range” may cover a partition of the electromagnetic spectrum from 1 nm to 400 nm, in particular from 100 nm to 400 nm, and can be subdivided into a number of ranges as recommended by the ISO standard ISO-21348, wherein the alternative PIN diode provided here may particularly be suitable for the Ultraviolet A range, abbreviated to “UVA”, from 400 nm to 315 nm and/or the Ultraviolet B range, abbreviated to “UVB” from 315 nm to 280 nm. For this purpose, the alternative PIN diode may exhibit the same or a similar arrangement as the PIN diode comprising the amorphous silicon as described above and/or below, wherein the amorphous silicon (a-Si) or the hydrogenated amorphous silicon (a-Si:H), respectively, may at least partially be replaced by an amorphous alloy of silicon and carbon (a-SiC) or, preferably, by a hydrogenated amorphous silicon carbon alloy (a-SiC:H). This kind of alternative PIN diode may exhibit a high external quantum efficiency within the UV wavelength range preferably, over the complete UVA and UVB wavelength range from 280 nm to 400 nm. Herein, the hydrogenated amorphous silicon carbon alloy (a-SiC:H) may, preferably, be produced in a plasma-enhanced deposition process, typically by using SiH₄ and CH₄ as process gases. However, other production methods for providing a-SiC:H may also be applicable.

As known from prior art, a layer comprising the hydrogenated amorphous silicon carbon alloy a-SiC:H may usually exhibit a hole mobility which may significantly be smaller compared to an electron mobility in a layer comprising the hydrogenated amorphous silicon a-Si:H. Thus, the layer comprising a-SiC:H may be employed as a p-doped hole extraction layer, particularly arranged on the side of a device at which the light beam may enter the device. As a result of this arrangement, a distance over which holes might have to travel in order to be able to contribute to the photocurrent can considerably reduced. Consequently, it may, thus, be advantageous to provide a PIN diode in the detector according to the present invention in which the p-type semiconductor layer may exhibit a thickness from 2 nm to 40 nm, preferably from 4 nm to 10 nm, such as about 5 nm. For example, the p-type semiconductor layer may exhibit a thickness of 10 nm. The n-type semiconductor layer may exhibit a thickness of 20 nm. The i-type semiconductor layer, which may, preferably, also comprise a-SiC:H, may exhibit a thickness of 300 to 500 nm. Still, a particular light beam having a wavelength in the UV spectral range, especially within the UVA spectral range and/or the UVB spectral range, which may impinge on a side of the PIN diode comprising this kind of thin p-type semiconductor layer may be absorbed therein. In addition, this kind of thin layer may, further, allow electrons to traverse the layer and, thus, to enter into the adjacent i-type semiconductor layer of the PIN diode. Herein, the i-type semiconductor layer which may, preferably, also comprise a-SiC:H may, equally, exhibit a thickness from 2 nm to 20 nm, preferably from 4 nm to 10 nm, such as about 5 nm. However, other kinds of PIN diodes in which at least one of the semiconductor layers may comprise at least partially a-SiC:H may also be feasible.

As described above, non-linear effects which are involved in the production of the photocurrent may constitute a basis for the occurrence of the FiP effect in the longitudinal sensor being equipped with a PIN diode comprising these kinds of semiconductor layers. As a result, this kind of longitudinal sensors may, in particular, be used in applications in which a UV response may be required, such as for being able to observe optical phenomena in the UV spectral range, or suitable, such as when an active target which may emit at least one wavelength within the UV spectral range might be used.

Alternatively, a further PIN diode may be provided which could preferably be employed in the detector according to the present invention when the incident beam may have a wavelength within the NIR spectral range. As used herein, the term “NIR spectral range”, which may also abbreviated to “IR-A”, may cover a partition of the electromagnetic spectrum from 760 nm to 1400 nm as recommended by the ISO standard ISO-21348. For this purpose, the alternative PIN diode may exhibit the same or a similar arrangement as the PIN diode comprising the amorphous silicon as described above and/or below, wherein the amorphous silicon (a-Si) or the hydrogenated amorphous silicon (a-Si:H), respectively, may at least partially be replaced by one of a microcrystalline silicon (μc-Si), preferably a hydrogenated microcrystalline silicon (μc-Si:H), or an amorphous alloy of germanium and silicon (a-GeSi), preferably a hydrogenated amorphous germanium silicon alloy (a-GeSi:H). This further kind of PIN diode may exhibit a high external quantum efficiency over a wavelength range which may at least partially cover the NIR wavelength range from 760 nm to 1400 nm, in particular at least from 760 nm to 1000 nm. By way of example, the PIN diode comprising μc-Si has a non-negligible quantum efficiency over a wavelength range which approximately extends from 500 nm to 1100 nm.

Herein, the hydrogenated microcrystalline silicon (μc-Si:H) may, preferably, be produced from a gaseous mixture of SiH4 and CH4. As a result, a two-phase material on a substrate comprising microcrystallites having a typical size of 5 nm to 30 nm and being located between ordered columns of the substrate material spaced apart 10 nm to 200 nm with respect to each other may be obtained. However, another production method for providing μc-Si:H may also be applicable which may, however not necessarily, lead to an alternative arrangement of the μc-Si:H. Further, the hydrogenated amorphous germanium silicon alloy (a-GeSi:H) may, preferably, be produced by using SiH4, GeH4, and H2 as process gases within a common reactor. Also here, other production methods for providing a-GeSi:H may be feasible.

Comparing both μc-Si:H and a-GeSi:H to a-Si:H, the semiconductor layers comprising μc-Si:H and a-GeSi:H may have a similar or an increased disorder-induced localization of charge carriers, thus, exhibiting a considerably non-linear frequency response. As described above, this may constitute a basis for the occurrence of the FiP effect in the longitudinal sensor being equipped with a PIN diode comprising these kinds of semiconductor layers. As a result, this kind of longitudinal sensors may, in particular, be used in applications in which a NIR response may be required, such as in night vision or fog vision, or suitable, such as when an active target emitting at least one wavelength within the NIR spectral range may be used, for example, in a case in which it might be advantageous when animals or human beings may be left undisturbed by using an NIR illumination source.

The longitudinal optical sensor may be at least partially transparent, in particular transparent or semitransparent. The layer setup may be adapted to be traversed by the incident light beam in an order in which the layers are arranged within the layer setup. Each of the layers in the layer setup may be at least partially transparent or translucent. Thus, the intrinsic semiconductor layer may have a thickness as small as possible. In particular, the intrinsic semiconductor layer may be a thin film layer, with a thickness from 100 nm to 300 nm, in particular from 150 nm to 200 nm. The thickness of the intrinsic semiconductor layers may be chosen similar to layer thickness as used in high performance tandem cells. Thus, using thin intrinsic semiconductor layers may allow manufacturing at least partially transparent longitudinal optical sensors.

The detector may further comprise at least one imaging device and/or at least one PSD. The longitudinal optical sensor and the imaging device and/or the PSD may be arranged on a common optical axis. The longitudinal optical sensor and the imaging device and/or PSD may be arranged in a stack, as separated devices, or as monolithic device.

For example, the longitudinal optical sensor and the imaging device and/or the PSD may be arranged in a stack. The imaging device and/or the PSD may be situated in a direction of light propagating from the object to the detector behind the transparent longitudinal optical sensor. In this case, the PSD may be a standard quadrant detector or an opaque silicon based PSD. Additionally or alternatively, as an example, the detector according to the present invention may comprise one or more PSDs disclosed in R. A. Street (Ed.): Technology and Applications of Amorphous Silicon, Springer-Verlag Heidelberg, 2010, pp. 346-349. Additionally or alternatively, the imaging device may be based on intransparent inorganic materials, such as known CCD sensors and/or CMOS sensors.

For example, the PSD may be arranged in a direction of light propagating from the object to the detector in front of the longitudinal optical sensor. The PSD may be at least partially transparent or semitransparent. A semitransparent PSD may be realized by using a metal insulator semiconductor (MIS) layout. The PSD may comprise at least one photo sensitive area, in particular a photo-active layer. The photo-active layer may be silicon based, in particular the photoactive layer of the PSD may comprise one or more of a-Si:H, a-SiGe:H, a-Se:H and μc-Si:H. The PSD may have a PIN structure. Herein, the photo-active layer comprising a-Se:H may be sensitive in the X-ray or IR wavelength region. An intrinsic semiconductor layer of the PIN structure may be designed such that the PSD is at least partially transparent or semitransparent. In particular, a thickness of the intrinsic semiconductor layer may be from 100 nm to 2000 nm, in particular from 400 to 700 nm. The PSD may comprise at least four electrodes. The electrodes may be designed as extended parallel electrodes. The electrodes may comprise sputtered or atmospheric pressure chemical vapour deposited (APCVD) transparent conductive oxide (TCO). In particular, the electrodes may comprise a low-conductivity layer, in particular indium tin oxide (ITO) or fluorine doped tin oxide (FTO). The PSD may have a square or quadrant detector. For example, the PSD may be a tetra-lateral type PSD having the four electrodes arranged along each side of the square or quadrant on a surface of the PSD. For example, the PSD may be a duo-lateral type PSD having a pair of the four electrodes on each of two surfaces of the PSD, in particular a pair of electrodes on a front surface and a pair of electrodes on a back surface of the PSD, wherein the pairs of electrodes are arranged at right angles. This type of PSD may have improved linearity and sensitivity compared to the tetra-lateral PSD designs.

In a preferred embodiment, the longitudinal optical sensor and the transversal optical sensor may be arranged in a monolithic device, in particular the longitudinal optical sensor and the transversal optical sensor may be arranged within one layer setup. In particular, the longitudinal optical sensor and the transversal optical sensor may be manufactured as one layer setup. Such an arrangement may allow miniaturizing the detector.

For example, each of the layers in the layer setup but the last layer in the setup to be traversed by the incident light beam may be at least partially transparent or translucent. For example, the layer setup may comprise layers configured to serve as FiP device. For example, the layer setup may comprise at least two FiP devices, in particular the layer setup may comprise a plurality of FiP devices. The last layer of the layer setup may be a transversal optical sensor, in particular a PSD, e.g. an opaque silicon based PSD. The layer setup arrangement of FiP device and transversal optical sensor may allow miniaturizing the detector. The layer setup may comprise in a direction of propagation of the light beam in addition to the transversal optical sensor at least one additional layer which may not be traversed by the incident light beam.

For example, the first layer of the layer setup to be traversed by the incident light beam may be designed as transparent PSD. With respect to design of the PSD, reference can be made to the description of the PSD which may be arranged in a direction of light propagating from the object to the detector in front of the longitudinal optical sensor, as described above.

Two adjacent PN structures and/or PIN structures may share one of the electrode layers as a common electrode layer. For example, in a direction of the propagation of the incident light beam a first electrode layer may be arranged adjacent to a first PN structure. In a direction of the propagation of the incident light beam the layers of the first PN structure may have following order: p-type semiconductor layer, n-type semiconductor layer. Optionally at least one intrinsic semiconductor layer may be arranged between the p-type semiconductor layer and the n-type semiconductor layer. A second electrode layer may be arranged in between the first and a second PN structure. In a direction of the propagation of the incident light beam the layers of the second PN structure may have following order: n-type semiconductor layer, p-type semiconductor layer. Optionally at least one intrinsic semiconductor layer may be arranged between the p-type semiconductor layer and the n-type semiconductor layer. A third electrode layer may be arranged subsequent to the second PN structure. The first and second electrode layers together with the first PN structure may form a first photodiode. The third and second electrode layers together with the second PN structure may form a second photodiode. Such an arrangement may allow miniaturizing the detector.

The PSD may be designed for one-dimensional position sensing (1D-PSD) and/or for two-dimensional position sensing (2D-PSD). The 1D-PSD may be configured to determine one of the transversal coordinates x or y. The 2D-PSD may be configured to determine both of the transversal coordinates x and y simultaneously. For example, the PSD may be designed as thin-film detector comprising one or more of a-Si:H, μc-Si:H, CdTe, nanoparticle material or organic material. As outlined above, the PSD, in particular the 2D-PSD, may be arranged in a direction of light propagating from the object to the detector in front of the longitudinal optical sensor. Additionally or alternatively, the last layer of the layer setup may be a PSD, in particular the 2D-PSD. For example, the 2D-PSD may be a tetra-lateral type PSD having the four electrodes arranged along each side of the square or quadrant on a surface of the PSD. Tetra-lateral type 2D-PSDs may suffer from distortion of the x, y-coordinates due to electric field distortion. Thus, the PSD may comprise structured electrodes in order to prevent electric field distortion.

Using structured electrodes, however, may result in enhanced complexity of detector design. In addition, electric field distortion may not be excluded completely at large spot size in the sensor region. Furthermore, in case of arranging the longitudinal optical sensor in front of the PSD, the PSD will have a larger noise contribution, because the area resistance of the PSD results in a inherently higher noise compared to a non-PSD-detector. The longitudinal optical sensor may be adapted to operate as FiP-device and at the same time as PSD. In particular, the detector may comprise a combined device adapted to operate as longitudinal optical sensor and at the same time as transversal optical sensor. The longitudinal optical sensor may be adapted to operate as a FiP-device and at the same time as PSD adapted for one-dimensional position sensing. In order to operate as a PSD, at least one electrode of the longitudinal optical sensor may be designed as a split-electrode. For example, the split-electrode may comprise at least two parts. A relationship and/or ratio of currents of the parts of the split-electrode may be independent from the size of the currents and be used to determine the position. For details, reference may be made e.g. to WO 2014/097181 A1. In order to operate as a FiP-device a total current of the whole split-electrode may be used. For example, the longitudinal optical sensor may comprise two cells, wherein each cell may comprise at least one PIN structure and/or PN structure and two electrode layers. The two cells may share one of the electrode layers such that the two cells have a common electrode layer. The common electrode layer may be designed as common anode. Each cell may be configured as FiP-device and at the same time as 1D-PSD. Each cell may comprise a semi-transparent thin-film detector such as one or more of an a-Si:H thin-film detector, a μc-Si:H, CdTe, a nanoparticle thin-film detector or an organic thin-film detector. The 1D-PSD may comprise at least two electrodes on the surface of the PSD. The two electrodes on the surface of the 1D-PSD may be designed as cathodes. The two cells may be rotated by 90° to each other such that one cell is adapted to determine the transversal coordinate x and the other cell the transversal coordinate y. Electrode contacts of the anode and cathode electrode layers may be arranged on two sides of a cell opposite to each other. Unlike in 2D-PSDs, the 1D-PSD function may be geometrically easily achieved if one of the electrodes of each cell is made with a high sheet resistance.

Designing the longitudinal optical sensor to be adapted to operate as FiP-device and at the same time as PSD may allow simplifying the detector design. In addition, designing the longitudinal optical sensor to be adapted to operate as FiP-device and at the same time as PSD may allow to reduce an amount of detector components and, thus, elements on a bill of materials. Further, using 1 D-PSDs instead of a 2D-PSD may be advantageous because noise may be distributed to two cells and both cells show a same sensor behavior. Further, using 1 D-PSDs instead of a 2D-PSD may be advantageous because distortion is prevented.

The layer setup may further comprise at least one substrate layer comprising a layer of an opaque or transparent substrate, for example glass, crystalline silicon or a transparent or intransparent organic polymer. For example, one or both of a first layer of the layer setup or a last layer of the layer setup may be designed as substrate layer.

Two adjacent electrode layers having the same polarity may be separated from each other by an insulating layer. The insulating layer may be at least partially transparent or at least partially translucent. The insulating layer may comprise a layer of one of glass, quartz, or a transparent organic polymer. Additionally or alternatively, the longitudinal optical sensor may comprise at least one spacer layer, in particular an optical spacer layer, wherein the spacer layer is designed to separate a first photodiode and a second photodiode. The spacer layer may comprise a layer of one of glass, quartz, or a transparent organic polymer. Using an optical spacer layer and/or at least one insulating layer of an appropriate thickness may allow to set a distance between two PN and/or PIN structures. In such an embodiment, wherein the longitudinal optical sensor may have at least one insulating layer and/or a spacer layer, the layer setup further comprises a fourth electrode layer. The first and second electrode layers together with the first PN and/or PIN structure may form a first photodiode. The third and fourth electrode layers together with the second PN and/or PIN structure may form a second photodiode. In a direction of the propagation of the incident light beam the layers of the first PN structure may have following order: p-type semiconductor layer, optionally an intrinsic semiconductor layer, n-type semiconductor layer. In a direction of the propagation of the incident light beam the layers of the second PN structure may have following order: p-type semiconductor layer, optionally an intrinsic semiconductor layer, n-type semiconductor layer.

Each of the photodiodes may be configured to be addressed individually. Each of the electrode layers may be connectable and separately addressable. Hence, a photocurrent generated by one of the photodiodes may be determined separately from a photocurrent generated by another photodiode. A first photodiode may be designed to generate at least a first longitudinal sensor signal and a second photodiode may be designed to generate at least a second longitudinal sensor signal, wherein the evaluation device may be adapted to determine the first longitudinal optical sensor signal and the second longitudinal sensor signal simultaneously. The photodiodes may be arranged such that the first longitudinal optical sensor signal may be independent from the second longitudinal optical sensor signal. Thus, it may be possible to determine the longitudinal coordinate of the object unambiguously.

The electrode layers may comprise electrically conducting material. The electrode layers may be at least partially transparent. The electrode layers may comprise transparent conductive oxide (TCO), in particular one or more of indium tin oxide (ITO), zinc oxide (ZnO), Fluorine-doped tin oxide (FTO), aluminum-doped zinc oxide (AZO), antimony tin oxide (ATO). At least one of the electrode layers may be designed as reflective electrode. The reflective electrode may be arranged as last layer of the layer setup to be traversed by the incident light beam. The layer setup may comprise in a direction of propagation of the light beam in addition to the reflective electrode at least one additional layer which may not be traversed by the incident light beam.

As generally used, the term “partially transparent” refers to that the respective layer or device being adapted to be traversed by the incident light beam. Generally, layers or devices may be transparent, semitransparent, or intransparent. Thus, as an example, a layer may be transparent and adapted to transmit more than 50%, preferably at least 90% and, more preferably, at least 99% of the power of the light beam or semitransparent and adapted to transmit at least 1%, preferably at least 10% and, more preferably, at least 25% up to 50% of the power of the light beam.

Layers of the layer setup, in particular a photodiode of the layer setup, may be transparent or semitransparent over one or more predefined wavelength ranges. Each of the photodiodes may provide different spectral sensitivities. Thus, as an example, each of the at least two photodiodes may have a differing spectral sensitivity. As used herein, the term spectral sensitivity generally refers to the fact that the respective sensor signal of the corresponding photodiode, for the same power of the light beam, may vary with the wavelength of the light beam. Thus, generally, at least two of the same kind of optical sensors may differ with regard to their spectral properties. This embodiment generally may be achieved by using different types of optical filters and/or different types of absorbing materials for the respective photodiodes. For example, each of the photodiodes may be based on different material. Preferably, the photodiodes may be based on the same material.

In case a plurality of using at least two photodiodes which differ with regard to their respective spectral sensitivity, the evaluation device generally may be adapted to determine a color of the light beam by comparing sensor signals of the photodiodes having the differing spectral sensitivity. As used herein, the expression “determine a color” generally refers to the step of generating at least one item of spectral information about the light beam. The at least one item of spectral information may be selected from the group consisting of a wavelength, specifically a peak wavelength; color coordinates, such as CIE coordinates.

The determination of the color of the light beam may be performed in various ways which are generally known to the skilled person. Thus, the spectral sensitivities of the photodiodes may span a coordinate system in color space, and the signals provided by the photodiodes may provide a coordinate in this color space, as known to the skilled person for example from the way of determining CIE coordinates.

As an example, the detector may comprise two, three or more photodiodes of the same kind in the layer setup. Thereof, at least two, preferably at least three, of the photodiodes may have differing spectral sensitivities. Further, the evaluation device may be adapted to generate at least one item of color information for the light beam by evaluating the signals of the photodiodes having differing spectral sensitivities. As an example, at least three photodiodes of the same kind being spectrally sensitive photodiodes may be contained in the layer setup. Thus, e.g., the spectrally sensitive photodiodes may comprise at least one red sensitive photodiode, the red sensitive photodiode having a maximum absorption wavelength λr in a spectral range 600 nm<λr<780 nm, wherein the spectrally sensitive photodiodes further comprise at least one green sensitive photodiodes, the green sensitive photodiode having a maximum absorption wavelength λg in a spectral range 490 nm<λg<600 nm, wherein the spectrally sensitive photodiodes further may comprise at least one blue sensitive photodiode, the blue sensitive photodiode having a maximum absorption wavelength λb in a spectral range 380 nm<λb<490 nm. As an example, at least two photodiodes of the same kind being spectrally sensitive photodiodes may be contained in the layer setup. The spectrally sensitive photodiodes may comprise at least one first photodiode having a maximum absorption wavelength in a first spectral range in the NIR wavelength region and at least one second photodiode having a maximum absorption wavelength in a second spectral range in the NIR wavelength region, different to the first spectral range.

The evaluation device may be adapted to generate at least two color coordinates, preferably at least three color coordinates, wherein each of the color coordinates is determined by dividing a signal of one of the spectrally sensitive optical sensors by a normalization value. As an example, the normalization value may contain a sum of the signals of all spectrally sensitive photodiodes. Additionally or alternatively, the normalization value may contain a detector signal of a white detector.

The at least one item of color information may contain the color coordinates. The at least one item of color information may, as an example, contain CIE coordinates.

In addition to the preferred at least two, more preferably at least three, spectrally sensitive photodiodes, the detector may further comprise at least one white photodiode, wherein the white photodiode may be adapted to absorb light in an absorption range of all spectrally sensitive photodiodes. Thus, as an example, the white photodiode may have an absorption spectrum absorbing light all over the visible spectral range.

The detector further may comprise at least one transversal optical sensor for determining at least one transversal position of the at least one light beam traveling from the object to the detector, wherein the transversal optical sensors may be designed to generate at least one transversal sensor signal, wherein the evaluation device may be further configured to determine at least one transversal coordinate of the object by evaluating the transversal sensor signal. As used herein, the term “transversal optical sensor” generally refers to a device which is adapted to determine a transversal position of at least one light beam traveling from the object to the detector. With regard to the term position, reference may be made to the definition above. Thus, preferably, the transversal position may be or may comprise at least one coordinate in at least one dimension perpendicular to an optical axis of the detector. As an example, the transversal position may be a position of a light spot generated by the light beam in a plane perpendicular to the optical axis, such as on a light-sensitive sensor surface of the transversal optical sensor. As an example, the position in the plane may be given in Cartesian coordinates and/or polar coordinates. Other embodiments are feasible. For potential embodiments of the transversal optical sensor, reference may be made to WO 2014/097181 A1. However, other embodiments are feasible and will be outlined in further detail below.

The transversal optical sensor may provide at least one transversal sensor signal. Herein, the transversal sensor signal may generally be an arbitrary signal indicative of the transversal position. As an example, the transversal sensor signal may be or may comprise a digital and/or an analog signal. As an example, the transversal sensor signal may be or may comprise a voltage signal and/or a current signal. Additionally or alternatively, the transversal sensor signal may be or may comprise digital data. The transversal sensor signal may comprise a single signal value and/or a series of signal values. The transversal sensor signal may further comprise an arbitrary signal which may be derived by combining two or more individual signals, such as by averaging two or more signals and/or by forming a quotient of two or more signals

As outlined above, the transversal optical sensor may be a PSD. The longitudinal optical sensor and the transversal optical sensor may be arranged in a monolithic device. The layer setup further may comprise at least one layer adapted to act as a transversal optical sensor. Such an arrangement may allow miniaturizing the detector. In one embodiment, the layer adapted to act as a transversal optical sensor may be intransparent and arranged as the last layer in the setup to be to be traversed by the incident light beam. In this embodiment, the last layer of the layer setup may be an opaque transversal optical sensor. For example, the PSD may be a standard quadrant detector or an opaque silicon based PSD. For example, the position sensitive device may be based on intransparent inorganic materials, such as known CCD sensors and/or CMOS sensors. In one embodiment, the layer adapted to act as a transversal optical sensor may be at least partially transparent or translucent. The layer adapted to act as transversal optical sensor may be arranged as first layer in the setup to be traversed by the incident light beam. However, other positions within the layer setup are feasible.

As used herein, the term “evaluation device” generally refers to an arbitrary device designed to generate the items of information, i.e. the at least one item of information on the position of the object. As an example, the evaluation device may be or may comprise one or more integrated circuits, such as one or more application-specific integrated circuits (ASICs) and/or one or more Field Programmable Gate Arrays (FPGAs), and/or one or more digital signal processors (DSPs), and/or one or more data processing devices, such as one or more computers, preferably one or more microcomputers and/or microcontrollers. Additional components may be comprised, such as one or more preprocessing devices and/or data acquisition devices, such as one or more devices for receiving and/or preprocessing of the sensor signals, such as one or more AD-converters and/or one or more filters. As used herein, the sensor signal may generally refer to one of the longitudinal sensor signal and, if applicable, to the transversal sensor signal.

Further, the evaluation device may comprise one or more data storage devices. Further, as outlined above, the evaluation device may comprise one or more interfaces, such as one or more wireless interfaces and/or one or more wire-bound interfaces.

The at least one evaluation device may be adapted to perform at least one computer program, such as at least one computer program performing or supporting the step of generating the items of information. As an example, one or more algorithms may be implemented which, by using the sensor signals as input variables, may perform a predetermined transformation into the position of the object.

The evaluation device may particularly comprise at least one data processing device, in particular an electronic data processing device, which can be designed to generate the items of information by evaluating the sensor signals. Thus, the evaluation device is designed to use the sensor signals as input variables and to generate the items of information on the transversal position and the longitudinal position of the object by processing these input variables. The processing can be done in parallel, subsequently or even in a combined manner. The evaluation device may use an arbitrary process for generating these items of information, such as by calculation and/or using at least one stored and/or known relationship. Besides the sensor signals, one or a plurality of further parameters and/or items of information can influence said relationship, for example at least one item of information about a modulation frequency. The relationship can be determined or determinable empirically, analytically or else semi-empirically. Particularly preferably, the relationship comprises at least one calibration curve, at least one set of calibration curves, at least one function or a combination of the possibilities mentioned. One or a plurality of calibration curves can be stored for example in the form of a set of values and the associated function values thereof, for example in a data storage device and/or a table. Alternatively or additionally, however, the at least one calibration curve can also be stored for example in parameterized form and/or as a functional equation. Separate relationships for processing the sensor signals into the items of information may be used. Alternatively, at least one combined relationship for processing the sensor signals is feasible. Various possibilities are conceivable and can also be combined.

By way of example, the evaluation device can be designed in terms of programming for the purpose of determining the items of information. The evaluation device can comprise in particular at least one computer, for example at least one microcomputer. Furthermore, the evaluation device can comprise one or a plurality of volatile or nonvolatile data memories. As an alternative or in addition to a data processing device, in particular at least one computer, the evaluation device can comprise one or a plurality of further electronic components which are designed for determining the items of information, for example an electronic table and in particular at least one look-up table and/or at least one application-specific integrated circuit (ASIC), and/or at least one digital signal processor (DSP), and/or at least one field programmable gate array (FPGA).

The detector has, as described above, at least one evaluation device. In particular, the at least one evaluation device can also be designed to completely or partly control or drive the detector, for example by the evaluation device being designed to control at least one illumination source and/or to control at least one modulation device of the detector. The evaluation device can be designed, in particular, to carry out at least one measurement cycle in which one or a plurality of sensor signals, such as a plurality of sensor signals, are picked up, for example a plurality of sensor signals of successively at different modulation frequencies of the illumination.

The evaluation device may be designed, as described above, to generate at least one item of information on the position of the object by evaluating the at least one sensor signal. Said position of the object can be static or may even comprise at least one movement of the object, for example a relative movement between the detector or parts thereof and the object or parts thereof. In this case, a relative movement can generally comprise at least one linear movement and/or at least one rotational movement. Items of movement information can for example also be obtained by comparison of at least two items of information picked up at different times, such that for example at least one item of location information can also comprise at least one item of velocity information and/or at least one item of acceleration information, for example at least one item of information about at least one relative velocity between the object or parts thereof and the detector or parts thereof. In particular, the at least one item of location information can generally be selected from: an item of information about a distance between the object or parts thereof and the detector or parts thereof, in particular an optical path length; an item of information about a distance or an optical distance between the object or parts thereof and the optional transfer device or parts thereof; an item of information about a positioning of the object or parts thereof relative to the detector or parts thereof; an item of information about an orientation of the object and/or parts thereof relative to the detector or parts thereof; an item of information about a relative movement between the object or parts thereof and the detector or parts thereof; an item of information about a two-dimensional or three-dimensional spatial configuration of the object or of parts thereof, in particular a geometry or form of the object. Generally, the at least one item of location information can therefore be selected for example from the group consisting of: an item of information about at least one location of the object or at least one part thereof; information about at least one orientation of the object or a part thereof; an item of information about a geometry or form of the object or of a part thereof, an item of information about a velocity of the object or of a part thereof, an item of information about an acceleration of the object or of a part thereof, an item of information about a presence or absence of the object or of a part thereof in a visual range of the detector.

The at least one item of location information can be specified for example in at least one coordinate system, for example a coordinate system in which the detector or parts thereof rest. Alternatively or additionally, the location information can also simply comprise for example a distance between the detector or parts thereof and the object or parts thereof. Combinations of the possibilities mentioned are also conceivable.

It shall further be noted that two or more of the above-mentioned devices, including the optical sensors and the evaluation device, may fully or partially be integrated into one or more devices. Generally, the evaluation device may fully or partially be integrated into at least one of the optical sensors. Additionally or alternatively, the evaluation device may fully or partially be integrated into a common device which performs both functions and which, as an example, may comprise one or more hardware components such as one or more ASICs and/or one or more FPGAs and/or one or more DSPs. Additionally or alternatively, the evaluation device may also fully or partially be implemented by using one or more software components. The degree of integration may also have an impact on the speed of evaluation and the maximum frequency. Thus, as outlined above, the detector may also fully or partially be embodied as a camera and/or may be used in a camera, suited for acquiring standstill images or suited for acquiring video clips.

The detector according to one or more of the above-mentioned embodiments may be modified and improved or even optimized in various ways, which will be briefly discussed in the following and which may also be implemented in various arbitrary combinations, as the skilled person will recognize.

Furthermore, the detector can have at least one modulation device for modulating the illumination, in particular for a periodic modulation, in particular a periodic beam interrupting device. A modulation of the illumination should be understood to mean a process in which a total power of the illumination is varied, preferably periodically, in particular with one or a plurality of modulation frequencies. In particular, a periodic modulation can be effected between a maximum value and a minimum value of the total power of the illumination. The minimum value can be 0, but can also be >0, such that, by way of example, complete modulation does not have to be effected. The modulation can be effected for example in a beam path between the object and the optical sensor, for example by the at least one modulation device being arranged in said beam path. Alternatively or additionally, however, the modulation can also be effected in a beam path between an optional illumination source—described in even greater detail below—for illuminating the object and the object, for example by the at least one modulation device being arranged in said beam path. A combination of these possibilities is also conceivable. The at least one modulation device can comprise for example a beam chopper or some other type of periodic beam interrupting device, for example comprising at least one interrupter blade or interrupter wheel, which preferably rotates at constant speed and which can thus periodically interrupt the illumination. Alternatively or additionally, however, it is also possible to use one or a plurality of different types of modulation devices, for example modulation devices based on an electro-optical effect and/or an acousto-optical effect. Once again alternatively or additionally, the at least one optional illumination source itself can also be designed to generate a modulated illumination, for example by said illumination source itself having a modulated intensity and/or total power, for example a periodically modulated total power, and/or by said illumination source being embodied as a pulsed illumination source, for example as a pulsed laser. Thus, by way of example, the at least one modulation device can also be wholly or partly integrated into the illumination source. Various possibilities are conceivable.

Accordingly, the detector can be designed in particular to detect at least two longitudinal sensor signals in the case of different modulations, in particular at least two longitudinal sensor signals at respectively different modulation frequencies. The evaluation device can be designed to generate the geometrical information from the at least two longitudinal sensor signals. As described in WO 2012/110924 A1 and WO 2014/097181 A1, it is possible to resolve ambiguities and/or it is possible to take account of the fact that, for example, a total power of the illumination is generally unknown. By way of example, the detector can be designed to bring about a modulation of the illumination of the object and/or at least one sensor region of the detector, such as at least one sensor region of the at least one longitudinal optical sensor, with a frequency of 0.05 Hz to 1 MHz, such as 0.1 Hz to 10 kHz. As outlined above, for this purpose, the detector may comprise at least one modulation device, which may be integrated into the at least one optional illumination source and/or may be independent from the illumination source. Thus, at least one illumination source might, by itself, be adapted to generate the above-mentioned modulation of the illumination, and/or at least one independent modulation device may be present, such as at least one chopper and/or at least one device having a modulated transmissibility, such as at least one electro-optical device and/or at least one acousto-optical device.

According to the present invention, it may be advantageous in order to apply at least one modulation frequency to the optical detector as described above. However, it may still be possible to directly determine the longitudinal sensor signal without applying a modulation frequency to the optical detector. As will be demonstrated below in more detail, an application of a modulation frequency may not be required under many relevant circumstances in order to acquire the desired longitudinal information about the object. As a result, the optical detector may, thus, not be required to comprise a modulation device which may further contribute to the simple and cost-effective setup of the spatial detector. As a further result, a spatial light modulator may be used in a time-multiplexing mode rather than a frequency-multiplexing mode or in a combination thereof.

As discussed in various of the above-mentioned applications which are included by reference, specifically in WO 2014/097181 A1, an ambiguity exists in the size of the light spot at equal distances before and after the focal point. Thus, specifically for resolving this ambiguity, the layer setup of the longitudinal optical sensor comprises at least two photodiodes, in particular at least two FiP devices, wherein the photodiodes are positioned at different positions in the layer setup along one or more beam paths of the light beam. Thus, by comparing the at least two longitudinal sensor signals and/or the results retrieved by the two or more photodiodes, it may be determined whether the focal point is located before the photodiodes (beam is typically widening), behind the photodiodes (beam is typically narrowing) or in between, wherein the latter often requires the use of three or more photodiodes. Thus, specifically, the evaluation device may be configured to determine the at least one longitudinal coordinate z of the object by evaluating the longitudinal sensor signals of at least two of the photodiodes. At least two of the photodiodes may be positioned at different positions along at least one beam path of the light beam, such that an optical path length between the object and the at least two photodiodes is non-identical.

The detector may further comprise one or more additional optical elements. As an example, the detector may comprise one or more lenses and/or one or more flat or curved reflective elements, as will be outlined in further detail below in the context of the transfer device. Specifically, however, the detector may further comprise at least one wavelength selective element, also referred to as at least one optical filter of filter element. The at least one optical filter, as an example, may comprise at least one transmissive filter or absorption filter, at least one grating, at least one dichroitic mirror or any combination thereof. Other types of wavelength selective elements may be used.

As outlined above, the detector may further comprise one or more additional elements such as one or more additional optical elements. Further, the detector may fully or partially be integrated into at least one housing. The detector specifically may comprise at least one transfer device, the transfer device being adapted to guide the light beam onto the longitudinal optical sensor and/or the transversal optical sensor. The transfer device may comprise one or more of: at least one lens, preferably at least one focus-tunable lens; at least one beam deflection element, preferably at least one mirror; at least one beam splitting element, preferably at least one of a beam splitting cube or a beam splitting mirror; at least one multi-lens system.

As outlined above, the detector may further comprise one or more optical elements, such as one or more lenses and/or one or more refractive elements, one or more mirrors, one or more diaphragms or the like. These optical elements which are adapted to modify the light beam, such as by modifying one or more of a beam parameter of the light beam, a width of the light beam or a direction of the light beam, above and in the following, are also referred to as a “transfer element” or “transfer device”. Thus, the detector may further comprise at least one transfer device, wherein the transfer device may be adapted to guide the light beam onto the at longitudinal optical sensor, such as by one or more of deflecting, focusing or defocusing the light beam. Specifically, the transfer device may comprise one or more lenses and/or one or more curved mirrors and/or one or more other types of refractive elements.

In case the detector comprises one or more transfer devices, the at least one transfer device specifically may have at least one focal length. Therein, the focal length may be fixed or variable. In the latter case, specifically, one or more focused tunable lenses may be comprised in the at least one transfer device. In this context, as an example, reference may be made to European patent application number 14 196 944.4, filed on Dec. 9, 2014, the full content of which is herewith included by reference. The focus-tunable lenses disclosed therein may also be used in the at least one optional transfer device of the detector according to the present invention.

As used herein, the term “focus-tunable lens” generally refers to an optical element being adapted to modify a focal position of a light beam passing the focus-tunable lens in a controlled fashion. The focus-tunable lens may be or may comprise one or more lens elements such as one or more lenses and/or one or more curved mirrors, with an adjustable or tunable focal length. The one or more lenses, as an example, may comprise one or more of a biconvex lens, a biconcave lens, a piano-convex lens, a plano-concave lens, a convex-concave lens, or a concave-convex lens. The one or more curved mirrors may be or may comprise one or more of a concave mirror, a convex mirror, or any other type of mirror having one or more curved reflective surfaces. Any arbitrary combination thereof is generally feasible, as the skilled person will recognize. Therein, a “focal position” generally refers to a position at which the light beam has the narrowest width. Still, the term “focal position” generally may refer to other beam parameters, such as a divergence, a Raleigh length or the like, as will be obvious to the person skilled in the art of optical design. Thus, as an example, the focus-tunable lens may be or may comprise at least one lens, the focal length of which may be changed or modified in a controlled fashion, such as by an external influence light, a control signal, a voltage or a current. The change in focal position may also be achieved by an optical element with switchable refractive index, which by itself may not be a focusing device, but which may change the focal point of a fixed focus lens when placed into the light beam. As further used in this context, the term “in a controlled fashion” generally refers to the fact that the modification takes place due to an influence which may be exerted onto the focus-tunable lens, such that the actual focal position of the light beam passing the focus-tunable lens and/or the focal length of the focus-tunable lens may be adjusted to one or more desired values by exerting an external influence on to the focus-tunable lens, such as by applying a control signal to the focus-tunable lens, such as one or more of a digital control signal, an analog control signal, a control voltage or a control current. Specifically, the focus-tunable lens may be or may comprise a lens element such as a lens or a curved mirror, the focal length of which may be adjusted by applying an appropriate control signal, such as an electrical control signal. Examples of focus-tunable lenses are known in the literature and are commercially available. As an example, reference may be made to the tunable lenses, preferably the electrically tunable lenses, as available by Optotune AG, CH-8953 Dietikon, Switzerland, which may be employed in the context of the present invention. Further, focus tunable lenses as commercially available from Varioptic, 69007 Lyon, France, may be used. For a review on focus-tunable lenses, specifically based on fluidic effects, reference may be made, e.g., to N. Nguyen: “Micro-optofluidic Lenses: A review”, Biomicrofluidics, 4, 031501 (2010) and/or to Uriel Levy, Romi Shamai: “Tunable optofluidic devices”, Microfluid Nanofluid, 4, 97 (2008). It shall be noted, however, that other principles of focus-tunable lenses may be used in addition or alternatively.

Various principles of focus-tunable lenses are known in the art and may be used within the present invention. Thus, firstly, the focus-tunable lens may comprise at least one transparent shapeable material, preferably a shapeable material which may change its shape and, thus, may change its optical properties and/or optical interfaces due to an external influence, such as a mechanical influence and/or an electrical influence. An actuator exerting the influence may specifically be part of the focus-tunable lens. Additionally or alternatively, the focus tunable lens may have one or more ports for providing at least one control signal to the focus tunable lens, such as one or more electrical ports. The shapeable material may specifically be selected from the group consisting of a transparent liquid and a transparent organic material, preferably a polymer, more preferably an electroactive polymer. Still, combinations are possible. Thus, as an example, the shapeable material may comprise two different types of liquids, such as a hydrophilic liquid and a lipophilic liquid. Other types of materials are feasible. The focus-tunable lens may further comprise at least one actuator for shaping at least one interface of the shapeable material. The actuator specifically may be selected from the group consisting of a liquid actuator for controlling an amount of liquid in a lens zone of the focus-tunable lens or an electrical actuator adapted for electrically changing the shape of the interface of the shapeable material. One embodiment of focus-tunable lenses are electrostatic focus-tunable lenses. Thus, the focus-tunable lens may comprise at least one liquid and at least two electrodes, wherein the shape of at least one interface of the liquid is changeable by applying one or both of a voltage or a current to the electrodes, preferably by electro-wetting. Additionally or alternatively, the focus tunable lens may be based on a use of one or more electroactive polymers, the shape of which may be changed by applying a voltage and/or an electric field.

A single focus-tunable lens or a plurality of focus-tunable lenses may be used. Thus, the focus-tunable lens may be or may comprise a single lens element or a plurality of single lens elements. Additionally or alternatively, a plurality of lens elements may be used which are interconnected, such as in one or more modules, each module having a plurality of focus-tunable lenses. Thus, as an example, the at least one focus-tunable lens may be or may comprise at least one lens array, such as a micro-lens array, such as disclosed in C. U. Murade et al., Optics Express, Vol. 20, No. 16, 18180-18187 (2012). Other embodiments are feasible, such as a single focus-tunable lens.

The at least one focus-tunable lens may be used in various ways. Thus, specifically, by using at least one focus tunable lens in the at least one optional transfer device, ambiguities in the determination of the z coordinate may be resolved. Thus, as explained e.g. in WO 2014/097181 A1, a beam waist or beam diameter of a light beam, specifically of a Gaussian ray, is symmetric before and after the focal point and, thus, an ambiguity exists in case the size of the light spot is determined in only one longitudinal position. Therefore, as proposed in WO 2014/097181 A1, the size of the light spot into different positions may be determined, which is also possible in the context of the present invention, in order to resolve the ambiguity and in order to determine the at least one z-coordinate of the object in a non-ambiguous fashion. For this purpose, as an example, two or more than two longitudinal optical sensors may be used, which preferably are positioned at different positions along an optical beam path and/or which are positioned in different partial beam paths, as will be explained in further detail below. Additionally or alternatively, however, the at least one optional focus-tunable lens may be used, and an evaluation according to the present invention may take place with at least two different adjustments, i.e. at least two different focal positions of the at least one focus-tunable lens. By shifting the focal position, the above-mentioned ambiguity may be resolved since the sizes of the beam spot measured, in one case, at a constant distance before the focal position and, in a second case, measured at the constant distance behind the focal position will behave differently when the focal position is changed. Thus, in one case, the size of the light spot will increase and in the other case decrease, or vice versa, as the skilled person easily may derive when looking at e.g. FIG. 5A or 5B of WO 2014/097181 A1.

Thus, by using the at least one focus-tunable lens, beam splitters or a splitting of the beam path into two or more partial beam paths may be avoided. Still, one or more intransparent optical sensors may be used. At least one focus-tunable lens can be used to record two or more images in a row, which, as an example, may be used as an input signal for the evaluation device. Thereby, a detector or a camera with only one beam path may be realized, such as by recording two or more images in a row with different lens focus of the at least one focus-tunable lens. The images may be used as an input for the at least one evaluation device.

Secondly, the at least one focus-tunable lens may be used for recording images in different object planes. Thus, by changing the focal length of the at least one focus-tunable lens, a 3-D imaging may take place.

Thus, generally, the at least one optional transfer device may comprise at least one focus-tunable lens. The detector, specifically the evaluation device, may be configured to subsequently record images in different object planes. Additionally or alternatively, the detector, specifically the evaluation device, may be configured to determine longitudinal coordinates of at least two different parts of the object having different longitudinal coordinates z by evaluating at least two different longitudinal sensor signals acquired at at least two different adjustments of the at least one focus-tunable lens. The detector, specifically the evaluation device, may be configured to resolve ambiguities in the determination of the at least one longitudinal coordinate z by comparing results obtained at at least two different adjustments of the at least one focus-tunable lens.

Further, additionally or alternatively, the at least one transfer device may comprise at least one multi-lens system, such as at least one array of lenses, specifically at least one micro-lens array. As used herein, a “multi-lens” system generally refers to a plurality of lenses, an “array of lenses” refers to a plurality of lenses arranged in a pattern, such as in a rectangular, circular, hexagonal or star-shaped pattern, specifically in a plane perpendicular to an optical axis of the detector. A “micro-lens array” refers to an array of lenses having a diameter or equivalent diameter in the submillimeter range, such as having a diameter or equivalent diameter of less than 1 mm, specifically 500 μm or less, more specifically 300 μm or less. By using at least one multi-lens system, specifically at least one array of lenses, more specifically at least one micro-lens array, optionally in conjunction with at least one further lens, such as at least one main lens, the detector may be embodied as one or both of a light field camera and/or a plenoptic camera. As used herein, a “light-field detector” generally refers to an optical detector which is configured to record information from at least two different object planes, preferably simultaneously. Further, as used herein, a “light-field camera” generally refers to a camera which is configured to record images from at least two different object planes, preferably simultaneously. As further used herein, a “plenoptic detector” generally refers to a detector having a plurality of lenses and/or a plurality of curved mirrors having differing focal points, such as a plurality of lenses and/or a plurality of curved mirrors being located in a plane perpendicular to an optical axis of the detector. Similarly, as used herein, a “plenoptic camera” generally refers to a camera having a plurality of lenses and/or a plurality of curved mirrors having differing focal points, such as a plurality of lenses and/or a plurality of curved mirrors being located in a plane perpendicular to an optical axis of the camera. The optics of the light-field detector and/or the light-field camera specifically may comprise at least one main lens or main lens system, and, additionally, at least one multi-lens system, specifically at least one array of lenses, more specifically at least one micro-lens array. The light-field detector and/or the light-field camera further comprises the at least one optical sensor, such as the at least one CCD and/or CMOS sensor, wherein the optical sensor may specifically be an image sensor. While recording an image, objects in a first object plane may be in focus, so that the image plane may coincide with the lenses of a plane of the multi-lens system, specifically of the at least one array of lenses, more specifically of the at least one micro-lens array. The image focused on this object plane may be obtained by summing up the nonlinear sensor signals or intensities below each lens, such as below each micro-lens.

The light beam which emerges from the object may travel first through the at least one transfer device and thereafter through the single transparent longitudinal optical sensor or a stack of the transparent longitudinal optical sensors until it may finally impinge on an imaging device. The transfer device can be designed to feed light propagating from the object to the detector to the optical sensors, wherein this feeding can optionally be effected by means of imaging or else by means of non-imaging properties of the transfer device. In particular the transfer device can also be designed to collect the electromagnetic radiation before the latter is fed to the transversal and/or longitudinal optical sensor. In addition, the at least one transfer device may have imaging properties. Consequently, the transfer device comprises at least one imaging element, for example at least one lens and/or at least one curved mirror, since, in the case of such imaging elements, for example, a geometry of the illumination on the sensor region can be dependent on a relative positioning, for example a distance, between the transfer device and the object. As used herein, the transfer device may be designed in such a way that the electromagnetic radiation which emerges from the object is transferred completely to the sensor region, for example is focused completely onto the sensor region, in particular if the object is arranged in a visual range of the detector.

Generally, the detector may further comprise at least one imaging device, i.e. a device capable of acquiring at least one image. The imaging device can be embodied in various ways. Thus, the imaging device can be for example part of the detector in a detector housing. Alternatively or additionally, however, the imaging device can also be arranged outside the detector housing, for example as a separate imaging device. Alternatively or additionally, the imaging device can also be connected to the detector or even be part of the detector. In a preferred arrangement, the stack of the transparent longitudinal optical sensors and the imaging device are aligned along a common optical axis along which the light beam travels. Thus, it may be possible to locate an imaging device in the optical path of the light beam in a manner that the light beam travels through the stack of the transparent longitudinal optical sensors until it impinges on the imaging device. However, other arrangements are possible.

As used herein, an “imaging device” is generally understood as a device which can generate a one-dimensional, a two-dimensional, or a three-dimensional image of the object or of a part thereof. In particular, the detector, with or without the at least one optional imaging device, can be completely or partly used as a camera, such as an IR camera, or an RGB camera, i.e. a camera which is designed to deliver three basic colors which are designated as red, green, and blue, on three separate connections. Thus, as an example, the at least one imaging device may be or may comprise at least one imaging device selected from the group consisting of: a pixelated organic camera element, preferably a pixelated organic camera chip; a pixelated inorganic camera element, preferably a pixelated inorganic camera chip, more preferably a CCD- or CMOS-chip; a monochrome camera element, preferably a monochrome camera chip; a multicolor camera element, preferably a multicolor camera chip; a full-color camera element, preferably a full-color camera chip. The imaging device may be or may comprise at least one device selected from the group consisting of a monochrome imaging device, a multi-chrome imaging device and at least one full color imaging device. A multi-chrome imaging device and/or a full color imaging device may be generated by using filter techniques and/or by using intrinsic color sensitivity or other techniques, as the skilled person will recognize. Other embodiments of the imaging device are also possible.

The imaging device may be designed to image a plurality of partial regions of the object successively and/or simultaneously. By way of example, a partial region of the object can be a one-dimensional, a two-dimensional, or a three-dimensional region of the object which is delimited for example by a resolution limit of the imaging device and from which electromagnetic radiation emerges. In this context, imaging should be understood to mean that the electromagnetic radiation which emerges from the respective partial region of the object is fed into the imaging device, for example by means of the at least one optional transfer device of the detector. The electromagnetic rays can be generated by the object itself, for example in the form of a luminescent radiation. Alternatively or additionally, the at least one detector may comprise at least one illumination source for illuminating the object.

In particular, the imaging device can be designed to image sequentially, for example by means of a scanning method, in particular using at least one row scan and/or line scan, the plurality of partial regions sequentially. However, other embodiments are also possible, for example embodiments in which a plurality of partial regions is simultaneously imaged. The imaging device is designed to generate, during this imaging of the partial regions of the object, signals, preferably electronic signals, associated with the partial regions. The signal may be an analogue and/or a digital signal. By way of example, an electronic signal can be associated with each partial region. The electronic signals can accordingly be generated simultaneously or else in a temporally staggered manner. By way of example, during a row scan or line scan, it is possible to generate a sequence of electronic signals which correspond to the partial regions of the object, which are strung together in a line, for example. Further, the imaging device may comprise one or more signal processing devices, such as one or more filters and/or analogue-digital-converters for processing and/or preprocessing the electronic signals.

Light emerging from the object can originate in the object itself, but can also optionally have a different origin and propagate from this origin to the object and subsequently toward the optical sensors. The latter case can be affected for example by at least one illumination source being used. The illumination source can be embodied in various ways. Thus, the illumination source can be for example part of the detector in a detector housing. Alternatively or additionally, however, the at least one illumination source can also be arranged outside a detector housing, for example as a separate light source. The illumination source can be arranged separately from the object and illuminate the object from a distance. Alternatively or additionally, the illumination source can also be connected to the object or even be part of the object, such that, by way of example, the electromagnetic radiation emerging from the object can also be generated directly by the illumination source. By way of example, at least one illumination source can be arranged on and/or in the object and directly generate the electromagnetic radiation by means of which the sensor region is illuminated. This illumination source can for example be or comprise an ambient light source and/or may be or may comprise an artificial illumination source. By way of example, at least one infrared emitter and/or at least one emitter for visible light and/or at least one emitter for ultraviolet light can be arranged on the object. By way of example, at least one light emitting diode and/or at least one laser diode can be arranged on and/or in the object. The illumination source can comprise in particular one or a plurality of the following illumination sources: a laser, in particular a laser diode, although in principle, alternatively or additionally, other types of lasers can also be used; a light emitting diode; an incandescent lamp; a neon light; a flame source; a heat source; an organic light source, in particular an organic light emitting diode; a structured light source. Alternatively or additionally, other illumination sources can also be used. It is particularly preferred if the illumination source is designed to generate one or more light beams having a Gaussian beam profile, as is at least approximately the case for example in many lasers. For further potential embodiments of the optional illumination source, reference may be made to one of WO 2012/110924 A1 and WO 2014/097181 A1. Still, other embodiments are feasible.

The at least one optional illumination source generally may emit light in at least one of: the ultraviolet spectral range, preferably in the range of 200 nm to 380 nm; the visible spectral range (380 nm to 780 nm); the infrared spectral range, preferably in the range of 780 nm to 3.0 micrometers. Most preferably, the at least one illumination source is adapted to emit light in the visible spectral range, preferably in the range of 500 nm to 780 nm, most preferably at 650 nm to 750 nm or at 690 nm to 700 nm. Herein, it is particularly preferred when the illumination source may exhibit a spectral range which may be related to the spectral sensitivities of the longitudinal sensors, particularly in a manner to ensure that the longitudinal sensor which may be illuminated by the respective illumination source may provide a sensor signal with a high intensity which may, thus, enable a high-resolution evaluation with a sufficient signal-to-noise-ratio.

In a further aspect of the present invention, a detector system for determining a position of at least one object is disclosed. The detector system comprises at least one detector according to the present invention, such as according to one or more of the embodiments disclosed above or according to one or more of the embodiments disclosed in further detail below. The detector system further comprising at least one beacon device adapted to direct at least one light beam towards the detector, wherein the beacon device is at least one of attachable to the object, holdable by the object and integratable into the object. Further details regarding the beacon device will be given below, including potential embodiments thereof. Thus, the at least one beacon device may be or may comprise at least one active beacon device, comprising one or more illumination sources such as one or more light sources like lasers, LEDs, light bulbs or the like. As an example, the light emitted by the illumination source may have a wavelength of 300-500 nm. Additionally or alternatively, the at least one beacon device may be adapted to reflect one or more light beams towards the detector, such as by comprising one or more reflective elements. Further, the at least one beacon device may be or may comprise one or more scattering elements adapted for scattering a light beam. Therein, elastic or inelastic scattering may be used. In case the at least one beacon device is adapted to reflect and/or scatter a primary light beam towards the detector, the beacon device may be adapted to leave the spectral properties of the light beam unaffected or, alternatively, may be adapted to change the spectral properties of the light beam, such as by modifying a wavelength of the light beam.

In a further aspect of the present invention, a human-machine interface for exchanging at least one item of information between a user and a machine is disclosed. The human-machine interface comprises at least one detector system according to the embodiments disclosed above and/or according to one or more of the embodiments disclosed in further detail below. Therein, the at least one beacon device is adapted to be at least one of directly or indirectly attached to the user or held by the user. The human-machine interface is designed to determine at least one position of the user by means of the detector system, wherein the human-machine interface is designed to assign to the position at least one item of information.

In a further aspect of the present invention, an entertainment device for carrying out at least one entertainment function is disclosed. The entertainment device comprises at least one human-machine interface according to the embodiment disclosed above and/or according to one or more of the embodiments disclosed in further detail below. The entertainment device is configured to enable at least one item of information to be input by a player by means of the human-machine interface. The entertainment device is further configured to vary the entertainment function in accordance with the information.

In a further aspect of the present invention, a tracking system for tracking a position of at least one movable object is disclosed. The tracking system comprises at least one detector system according to one or more of the embodiments referring to a detector system as disclosed above and/or as disclosed in further detail below. The tracking system further comprises at least one track controller. The track controller is adapted to track a series of positions of the object at specific points in time.

In a further aspect of the present invention, a camera for imaging at least one object is disclosed. The camera comprises at least one detector according to any one of the embodiments referring to a detector as disclosed above or as disclosed in further detail below.

In a further aspect of the present invention, a scanning system for determining at least one position of at least one object is provided. As used herein, the scanning system is a device which is adapted to emit at least one light beam being configured for an illumination of at least one dot located at at least one surface of the at least one object and for generating at least one item of information about the distance between the at least one dot and the scanning system. For the purpose of generating the at least one item of information about the distance between the at least one dot and the scanning system, the scanning system comprises at least one of the detectors according to the present invention, such as at least one of the detectors as disclosed in one or more of the embodiments listed above and/or as disclosed in one or more of the embodiments below.

Thus, the scanning system comprises at least one illumination source which is adapted to emit the at least one light beam being configured for the illumination of the at least one dot located at the at least one surface of the at least one object. As used herein, the term “dot” refers to an area, specifically a small area, on a part of the surface of the object which may be selected, for example by a user of the scanning system, to be illuminated by the illumination source. Preferably, the dot may exhibit a size which may, on one hand, be as small as possible in order to allow the scanning system to determine a value for the distance between the illumination source comprised by the scanning system and the part of the surface of the object on which the dot may be located as exactly as possible and which, on the other hand, may be as large as possible in order to allow the user of the scanning system or the scanning system itself, in particular by an automatic procedure, to detect a presence of the dot on the related part of the surface of the object.

For this purpose, the illumination source may comprise an artificial illumination source, in particular at least one laser source and/or at least one incandescent lamp and/or at least one semiconductor light source, for example, at least one light-emitting diode, in particular an organic and/or inorganic light-emitting diode. As an example, the light emitted by the illumination source may have a wavelength of 300-500 nm. On account of their generally defined beam profiles and other properties of handleability, the use of at least one laser source as the illumination source is particularly preferred. Herein, the use of a single laser source may be preferred, in particular in a case in which it may be important to provide a compact scanning system that might be easily storable and transportable by the user. The illumination source may thus, preferably be a constituent part of the detector and may, therefore, in particular be integrated into the detector, such as into the housing of the detector. In a preferred embodiment, particularly the housing of the scanning system may comprise at least one display configured for providing distance-related information to the user, such as in an easy-to-read manner. In a further preferred embodiment, particularly the housing of the scanning system may, in addition, comprise at least one button which may be configured for operating at least one function related to the scanning system, such as for setting one or more operation modes. In a further preferred embodiment, particularly the housing of the scanning system may, in addition, comprise at least one fastening unit which may be configured for fastening the scanning system to a further surface, such as a rubber foot, a base plate or a wall holder, such as a base plate or holder comprising a magnetic material, in particular for increasing the accuracy of the distance measurement and/or the handleability of the scanning system by the user.

Particularly, the illumination source of the scanning system may, thus, emit a single laser beam which may be configured for the illumination of a single dot located at the surface of the object. By using at least one of the detectors according to the present invention at least one item of information about the distance between the at least one dot and the scanning system may, thus, be generated. Hereby, preferably, the distance between the illumination system as comprised by the scanning system and the single dot as generated by the illumination source may be determined, such as by employing the evaluation device as comprised by the at least one detector. However, the scanning system may, further, comprise an additional evaluation system which may, particularly, be adapted for this purpose. Alternatively or in addition, a size of the scanning system, in particular of the housing of the scanning system, may be taken into account and, thus, the distance between a specific point on the housing of the scanning system, such as a front edge or a back edge of the housing, and the single dot may, alternatively, be determined.

Alternatively, the illumination source of the scanning system may emit two individual laser beams which may be configured for providing a respective angle, such as a right angle, between the directions of an emission of the beams, whereby two respective dots located at the surface of the same object or at two different surfaces at two separate objects may be illuminated. However, other values for the respective angle between the two individual laser beams may also be feasible. This feature may, in particular, be employed for indirect measuring functions, such as for deriving an indirect distance which may not be directly accessible, such as due to a presence of one or more obstacles between the scanning system and the dot or which may otherwise be hard to reach. By way of example, it may, thus, be feasible to determine a value for a height of an object by measuring two individual distances and deriving the height by using the Pythagoras formula. In particular for being able to keep a predefined level with respect to the object, the scanning system may, further, comprise at least one leveling unit, in particular an integrated bubble vial, which may be used for keeping the predefined level by the user.

As a further alternative, the illumination source of the scanning system may emit a plurality of individual laser beams, such as an array of laser beams which may exhibit a respective pitch, in particular a regular pitch, with respect to each other and which may be arranged in a manner in order to generate an array of dots located on the at least one surface of the at least one object. For this purpose, specially adapted optical elements, such as beam-splitting devices and mirrors, may be provided which may allow a generation of the described array of the laser beams. In particular, the illumination source may be directed to scan an area or a volume by using one or more movable mirrors to redirect the light beam in a periodic or non-periodic fashion. The illumination source may further be redirected using an array of micro-mirrors in order to provide in this manner a structured light source. The structured light source may be used to project optical features, such as points or fringes.

Thus, the scanning system may provide a static arrangement of the one or more dots placed on the one or more surfaces of the one or more objects. Alternatively, the illumination source of the scanning system, in particular the one or more laser beams, such as the above described array of the laser beams, may be configured for providing one or more light beams which may exhibit a varying intensity over time and/or which may be subject to an alternating direction of emission in a passage of time, in particular by moving one or more mirrors, such as the micro-mirrors comprised within the mentioned array of micro-mirrors. As a result, the illumination source may be configured for scanning a part of the at least one surface of the at least one object as an image by using one or more light beams with alternating features as generated by the at least one illumination source of the scanning device. In particular, the scanning system may, thus, use at least one row scan and/or line scan, such as to scan the one or more surfaces of the one or more objects sequentially or simultaneously. As non-limiting examples, the scanning system may be used in safety laser scanners, e.g. in production environments, and/or in 3D-scanning devices as used for determining the shape of an object, such as in connection to 3D-printing, body scanning, quality control, in construction applications, e.g. as range meters, in logistics applications, e.g. for determining the size or volume of a parcel, in household applications, e.g. in robotic vacuum cleaners or lawn mowers, or in other kinds of applications which may include a scanning step.

The optional transfer device can, as explained above, be designed to feed light propagating from the object to the detector to the at least two optical sensors, preferably successively. As explained above, this feeding can optionally be effected by means of imaging or else by means of non-imaging properties of the transfer device. In particular the transfer device can also be designed to collect the electromagnetic radiation before the latter is fed to one or more of the optical sensors. The optional transfer device can also, as explained in even greater detail below, be wholly or partly a constituent part of at least one optional illumination source, for example by the illumination source being designed to provide a light beam having defined optical properties, for example having a defined or precisely known beam profile, for example at least one Gaussian beam, in particular at least one laser beam having a known beam profile.

For potential embodiments of the optional illumination source, reference may be made to WO 2012/110924 A1. Still, other embodiments are feasible. Light emerging from the object can originate in the object itself, but can also optionally have a different origin and propagate from this origin to the object and subsequently toward the transversal and/or longitudinal optical sensor.

The latter case can be effected for example by at least one illumination source being used. This illumination source can for example be or comprise an ambient illumination source and/or may be or may comprise an artificial illumination source. By way of example, the detector itself can comprise at least one illumination source, for example at least one laser and/or at least one incandescent lamp and/or at least one semiconductor illumination source, for example, at least one light-emitting diode, in particular an organic and/or inorganic light-emitting diode. On account of their generally defined beam profiles and other properties of handleability, the use of one or a plurality of lasers as illumination source or as part thereof, is particularly preferred. The illumination source itself can be a constituent part of the detector or else be formed independently of the detector. The illumination source can be integrated in particular into the detector, for example a housing of the detector. Alternatively or additionally, at least one illumination source can also be integrated into the at least one beacon device or into one or more of the beacon devices and/or into the object or connected or spatially coupled to the object.

The light emerging from the beacon devices can accordingly, alternatively or additionally from the option that said light originates in the respective beacon device itself, emerge from the illumination source and/or be excited by the illumination source. By way of example, the electromagnetic light emerging from the beacon device can be emitted by the beacon device itself and/or be reflected by the beacon device and/or be scattered by the beacon device before it is fed to the detector. In this case, emission and/or scattering of the electromagnetic radiation can be effected without spectral influencing of the electromagnetic radiation or with such influencing. Thus, by way of example, a wavelength shift can also occur during scattering, for example according to Stokes or Raman. Furthermore, emission of light can be excited, for example, by a primary illumination source, for example by the object or a partial region of the object being excited to generate luminescence, in particular phosphorescence and/or fluorescence. Other emission processes are also possible, in principle. If a reflection occurs, then the object can have for example at least one reflective region, in particular at least one reflective surface. Said reflective surface can be a part of the object itself, but can also be for example a reflector which is connected or spatially coupled to the object, for example a reflector plaque connected to the object. If at least one reflector is used, then it can in turn also be regarded as part of the detector which is connected to the object, for example, independently of other constituent parts of the detector.

The beacon devices and/or the at least one optional illumination source generally may emit light in at least one of: the ultraviolet spectral range, preferably in the range of 200 nm to 380 nm; the visible spectral range (380 nm to 780 nm); the infrared spectral range, preferably in the range of 780 nm to 3.0 micrometers. For thermal imaging applications the target may emit light in the far infrared spectral range, preferably in the range of 3.0 micrometers to 20 micrometers. Most preferably, the at least one illumination source is adapted to emit light in the visible spectral range, preferably in the range of 500 nm to 780 nm, most preferably at 650 nm to 750 nm or at 690 nm to 700 nm.

The feeding of the light beam to the optical sensors, i.e. the longitudinal optical sensor and/or the transversal optical sensor, can be effected in particular in such a way that a light spot, for example having a round, oval or differently configured cross section, is produced on the sensor region of the optical sensor. By way of example, the detector can have a visual range, in particular a solid angle range and/or spatial range, within which objects can be detected. Preferably, the optional transfer device is designed in such a way that the light spot, for example in the case of an object arranged within a visual range of the detector, is arranged completely on the sensor region of the optical sensors. By way of example, a sensor region can be chosen to have a corresponding size in order to ensure this condition.

Further, the present invention discloses a method for determining a position of at least one object by using a detector, such as a detector according to the present invention, such as according to one or more of the embodiments referring to a detector as disclosed above or as disclosed in further detail below. Still, other types of detectors may be used.

The method comprises the following method steps, wherein the method steps may be performed in the given order or may be performed in a different order. Further, one or more additional method steps may be present which are not listed. Further, one, more than one or even all of the method steps may be performed repeatedly.

The method steps are as follows:
generating at least two longitudinal sensor signals by using at least one longitudinal optical sensor for determining a longitudinal position of at least one light beam traveling from the object to the detector, the longitudinal optical sensor having a layer setup, wherein the longitudinal optical sensor comprises at least two p-type semiconductor layers, at least two n-type semiconductor layers, and at least three individual electrode layers, wherein the p-type semiconductor layers and the n-type semi-conductor layers form at least two individual PN structures, wherein each of the PN structures is located between at least two of the electrode layers, thereby forming at least two photodiodes, wherein each of the two photodiodes has at least one longitudinal sensor region, wherein the longitudinal optical sensor is designed to generate at least two longitudinal sensor signals in a manner dependent on an illumination of the longitudinal sensor region by the light beam, wherein the longitudinal sensor signals, given the same total power of the illumination, are dependent on a beam cross-section of the light beam in the longitudinal sensor regions; and
evaluating the longitudinal sensor signals by using at least one evaluation device and generating at least one item of information on a longitudinal position of the object.

For details, options and definitions, reference may be made to the detector as discussed above. Thus, specifically, as outlined above, the method may comprise using the detector according to the present invention, such as according to one or more of the embodiments given above or given in further detail below.

In a further aspect of the present invention, use of the detector according to the present invention, such as according to one or more of the embodiments given above or given in further detail below, is proposed, for a purpose of use, selected from the group consisting of: a position measurement in traffic technology; an entertainment application; a security application; a surveillance application; a safety application; a human-machine interface application; a tracking application; a photography application; a use in combination with at least one time-of-flight detector; a use in combination with a structured light source; a use in combination with a stereo camera; a machine vision application; a robotics application; a quality control application; a manufacturing application; a use in combination with a structured illumination source; a use in combination with a stereo camera.

The detector may comprise one or more signal processing devices, such as one or more filters and/or analogue-digital-converters for processing and/or preprocessing the at least one signal.

The one or more signal processing devices may fully or partially be integrated into the optical sensor and/or may fully or partially be embodied as independent software and/or hardware components.

The object generally may be a living or non-living object. The detector system even may comprise the at least one object, the object thereby forming part of the detector system. Preferably, however, the object may move independently from the detector, in at least one spatial dimension.

The object generally may be an arbitrary object. In one embodiment, the object may be a rigid object. Other embodiments are feasible, such as embodiments in which the object is a non-rigid object or an object which may change its shape.

As will be outlined in further detail below, the present invention may specifically be used for tracking positions and/or motions of a person, such as for the purpose of controlling machines, gaming or simulation of sports. In this or other embodiments, specifically, the object may be selected from the group consisting of: an article of sports equipment, preferably an article selected from the group consisting of a racket, a club, a bat; an article of clothing; a hat; a shoe.

In an aspect of the present invention, as outlined above, the human-machine interface for exchanging at least one item of information between a user and a machine is disclosed. The human-machine interface comprises at least one detector system according to the present invention, such as to one or more of the embodiments disclosed above and/or according to one or more of the embodiments disclosed in further detail below. The beacon devices are adapted to be at least one of directly or indirectly attached to the user and held by the user. The human-machine interface is designed to determine at least one position of the user by means of the detector system. The human-machine interface further is designed to assign to the position at least one item of information.

In an aspect of the present invention, as outlined above, an entertainment device for carrying out at least one entertainment function is disclosed. The entertainment device comprises at least one human-machine interface according to the present invention. The entertainment device further is designed to enable at least one item of information to be input by a player by means of the human-machine interface. The entertainment device further is designed to vary the entertainment function in accordance with the information.

As outlined above, in a further aspect of the present invention, the tracking system for tracking a position of at least one movable object is disclosed. The tracking system comprises at least one detector system according to the present invention, such as to one or more of the embodiments disclosed above and/or according to one or more of the embodiments disclosed in further detail below. The tracking system further comprises at least one track controller, wherein the track controller is adapted to track a series of positions of the object at specific points in time.

Thus, generally, the devices according to the present invention, such as the detector, may be applied in various fields of uses. Specifically, the detector may be applied for a purpose of use, selected from the group consisting of: a position measurement in traffic technology; an entertainment application; a security application; a human-machine interface application; a tracking application; a photography application; a mapping application for generating maps of at least one space, such as at least one space selected from the group of a room, a building and a street; a mobile application; a webcam; an audio device; a dolby surround audio system; a computer peripheral device; a gaming application; a camera or video application; a security application; a surveillance application; an automotive application; a transport application; a medical application; a sports' application; a machine vision application; a vehicle application; an airplane application; a ship application; a spacecraft application; a building application; a construction application; a cartography application; a manufacturing application; a use in combination with at least one time-of-flight detector. Additionally or alternatively, applications in local and/or global positioning systems may be named, especially landmark-based positioning and/or navigation, specifically for use in cars or other vehicles (such as trains, motorcycles, bicycles, trucks for cargo transportation), robots or for use by pedestrians. Further, indoor positioning systems may be named as potential applications, such as for household applications and/or for robots used in manufacturing technology.

Thus, firstly, the devices according to the present invention may be used in mobile phones, tablet computers, laptops, smart panels or other stationary or mobile or wearable computer or communication applications. Thus, the devices according to the present invention may be combined with at least one active light source, such as a light source emitting light in the visible range or infrared spectral range, in order to enhance performance. Thus, as an example, the devices according to the present invention may be used as cameras and/or sensors, such as in combination with mobile software for scanning environment, objects and living beings. The devices according to the present invention may even be combined with 2D cameras, such as conventional cameras, in order to increase imaging effects. The devices according to the present invention may further be used for surveillance and/or for recording purposes or as input devices to control mobile devices, especially in combination with voice and/or gesture recognition. Thus, specifically, the devices according to the present invention acting as human-machine interfaces, also referred to as input devices, may be used in mobile applications, such as for controlling other electronic devices or components via the mobile device, such as the mobile phone. As an example, the mobile application including at least one device according to the present invention may be used for controlling a television set, a game console, a music player or music device or other entertainment devices.

Further, the devices according to the present invention may be used in webcams or other peripheral devices for computing applications. Thus, as an example, the devices according to the present invention may be used in combination with software for imaging, recording, surveillance, scanning or motion detection. As outlined in the context of the human-machine interface and/or the entertainment device, the devices according to the present invention are particularly useful for giving commands by facial expressions and/or body expressions. The devices according to the present invention can be combined with other input generating devices like e.g. mouse, keyboard, touchpad, microphone etc. Further, the devices according to the present invention may be used in applications for gaming, such as by using a webcam. Further, the devices according to the present invention may be used in virtual training applications and/or video conferences. Further, devices according to the present invention may be used to recognize or track hands, arms, or objects used in a virtual or augmented reality application, especially when wearing head mounted displays.

Further, the devices according to the present invention may be used in mobile audio devices, television devices and gaming devices, as partially explained above. Specifically, the devices according to the present invention may be used as controls or control devices for electronic devices, entertainment devices or the like. Further, the devices according to the present invention may be used for eye detection or eye tracking, such as in 2D- and 3D-display techniques, especially with transparent displays for augmented reality applications and/or for recognizing whether a display is being looked at and/or from which perspective a display is being looked at. Further, devices according to the present invention may be used to explore a room, boundaries, obstacles, in connection with a virtual or augmented reality application, especially when wearing a head-mounted display.

Further, the devices according to the present invention may be used in or as digital cameras such as DSC cameras and/or in or as reflex cameras such as SLR cameras. For these applications, reference may be made to the use of the devices according to the present invention in mobile applications such as mobile phones, as disclosed above.

Further, the devices according to the present invention may be used for security or surveillance applications. Thus, as an example, at least one device according to the present invention can be combined with one or more digital and/or analogue electronics that will give a signal if an object is within or outside a predetermined area (e.g. for surveillance applications in banks or museums). Specifically, the devices according to the present invention may be used for optical encryption. Detection by using at least one device according to the present invention can be combined with other detection devices to complement wavelengths, such as with IR, x-ray, UV-VIS, radar or ultrasound detectors. The devices according to the present invention may further be combined with an active infrared light source to allow detection in low light surroundings. The devices according to the present invention are generally advantageous as compared to active detector systems, specifically since the devices according to the present invention avoid actively sending signals which may be detected by third parties, as is the case e.g. in radar applications, ultrasound applications, LIDAR or similar active detector devices. Thus, generally, the devices according to the present invention may be used for an unrecognized and undetectable tracking of moving objects. Additionally, the devices according to the present invention generally are less prone to manipulations and irritations as compared to conventional devices.

Further, given the ease and accuracy of 3D detection by using the devices according to the present invention, the devices according to the present invention generally may be used for facial, body and person recognition and identification. Therein, the devices according to the present invention may be combined with other detection means for identification or personalization purposes such as passwords, finger prints, iris detection, voice recognition or other means. Thus, generally, the devices according to the present invention may be used in security devices and other personalized applications.

Further, the devices according to the present invention may be used as 3D barcode readers for product identification.

In addition to the security and surveillance applications mentioned above, the devices according to the present invention generally can be used for surveillance and monitoring of spaces and areas. Thus, the devices according to the present invention may be used for surveying and monitoring spaces and areas and, as an example, for triggering or executing alarms in case prohibited areas are violated. Thus, generally, the devices according to the present invention may be used for surveillance purposes in building surveillance or museums, optionally in combination with other types of sensors, such as in combination with motion or heat sensors, in combination with image intensifiers or image enhancement devices and/or photomultipliers. Further, the devices according to the present invention may be used in public spaces or crowded spaces to detect potentially hazardous activities such as commitment of crimes such as theft in a parking lot or unattended objects such as unattended baggage in an airport.

Further, the devices according to the present invention may advantageously be applied in camera applications such as video and camcorder applications. Thus, the devices according to the present invention may be used for motion capture and 3D-movie recording. Therein, the devices according to the present invention generally provide a large number of advantages over conventional optical devices. Thus, the devices according to the present invention generally require a lower complexity with regard to optical components. Thus, as an example, the number of lenses may be reduced as compared to conventional optical devices, such as by providing the devices according to the present invention having one lens only. Due to the reduced complexity, very compact devices are possible, such as for mobile use. Conventional optical systems having two or more lenses with high quality generally are voluminous, such as due to the general need for voluminous beam-splitters. Further, the devices according to the present invention generally may be used for focus/autofocus devices, such as autofocus cameras. Further, the devices according to the present invention may also be used in optical microscopy, especially in confocal microscopy.

Further, the devices according to the present invention generally are applicable in the technical field of automotive technology and transport technology. Thus, as an example, the devices according to the present invention may be used as distance and surveillance sensors, such as for adaptive cruise control, emergency brake assist, lane departure warning, surround view, blind spot detection, rear cross traffic alert, and other automotive and traffic applications. Further, the devices according to the present invention can also be used for velocity and/or acceleration measurements, such as by analyzing a first and second time-derivative of position information gained by using the detector according to the present invention. This feature generally may be applicable in automotive technology, transportation technology or general traffic technology. Applications in other fields of technology are feasible. A specific application in an indoor positioning system may be the detection of positioning of passengers in transportation, more specifically to electronically control the use of safety systems such as airbags. The use of an airbag may be prevented in case the passenger is located as such, that the use of an airbag will cause a severe injury.

In these or other applications, generally, the devices according to the present invention may be used as standalone devices or in combination with other sensor devices, such as in combination with radar and/or ultrasonic devices. Specifically, the devices according to the present invention may be used for autonomous driving and safety issues. Further, in these applications, the devices according to the present invention may be used in combination with infrared sensors, radar sensors, which are sonic sensors, two-dimensional cameras or other types of sensors. In these applications, the generally passive nature of the devices according to the present invention is advantageous. Thus, since the devices according to the present invention generally do not require emitting signals, the risk of interference of active sensor signals with other signal sources may be avoided. The devices according to the present invention specifically may be used in combination with recognition software, such as standard image recognition software. Thus, signals and data as provided by the devices according to the present invention typically are readily processable and, therefore, generally require lower calculation power than established stereovision systems such as LIDAR. Given the low space demand, the devices according to the present invention such as cameras may be placed at virtually any place in a vehicle, such as on a window screen, on a front hood, on bumpers, on lights, on mirrors or other places and the like. Various detectors according to the present invention such as one or more detectors based on the effect disclosed within the present invention can be combined, such as in order to allow autonomously driving vehicles or in order to increase the performance of active safety concepts. Thus, various devices according to the present invention may be combined with one or more other devices according to the present invention and/or conventional sensors, such as in the windows like rear window, side window or front window, on the bumpers or on the lights.

A combination of at least one device according to the present invention such as at least one detector according to the present invention with one or more rain detection sensors is also possible. This is due to the fact that the devices according to the present invention generally are advantageous over conventional sensor techniques such as radar, specifically during heavy rain. A combination of at least one device according to the present invention with at least one conventional sensing technique such as radar may allow for a software to pick the right combination of signals according to the weather conditions.

Further, the devices according to the present invention generally may be used as break assist and/or parking assist and/or for speed measurements. Speed measurements can be integrated in the vehicle or may be used outside the vehicle, such as in order to measure the speed of other cars in traffic control. Further, the devices according to the present invention may be used for detecting free parking spaces in parking lots.

Further, the devices according to the present invention may be used in the fields of medical systems and sports. Thus, in the field of medical technology, surgery robotics, e.g. for use in endoscopes, may be named, since, as outlined above, the devices according to the present invention may require a low volume only and may be integrated into other devices. Specifically, the devices according to the present invention having one lens, at most, may be used for capturing 3D information in medical devices such as in endoscopes. Further, the devices according to the present invention may be combined with an appropriate monitoring software, in order to enable tracking and analysis of movements. This may allow an instant overlay of the position of a medical device, such as an endoscope or a scalpel, with results from medical imaging, such as obtained from magnetic resonance imaging, x-ray imaging, or ultrasound imaging. These applications are specifically valuable e.g. in medical treatments where precise location information is important such as in brain surgery and long-distance diagnosis and tele-medicine. Further, the devices according to the present invention may be used in 3D-body scanning. Body scanning may be applied in a medical context, such as in dental surgery, plastic surgery, bariatric surgery, or cosmetic plastic surgery, or it may be applied in the context of medical diagnosis such as in the diagnosis of myofascial pain syndrome, cancer, body dysmorphic disorder, or further diseases. Body scanning may further be applied in the field of sports to assess ergonomic use or fit of sports equipment.

Body scanning may further be used in the context of clothing, such as to determine a suitable size and fitting of clothes. This technology may be used in the context of tailor-made clothes or in the context of ordering clothes or shoes from the internet or at a self-service shopping device such as a micro kiosk device or customer concierge device. Body scanning in the context of clothing is especially important for scanning fully dressed customers.

Further, the devices according to the present invention may be used in the context of people counting systems, such as to count the number of people in an elevator, a train, a bus, a car, or a plane, or to count the number of people passing a hallway, a door, an aisle, a retail store, a stadium, an entertainment venue, a museum, a library, a public location, a cinema, a theater, or the like. Further, the 3D-function in the people counting system may be used to obtain or estimate further information about the people that are counted such as height, weight, age, physical fitness, or the like. This information may be used for business intelligence metrics, and/or for further optimizing the locality where people may be counted to make it more attractive or safe. In a retail environment, the devices according to the present invention in the context of people counting may be used to recognize returning customers or cross shoppers, to assess shopping behavior, to assess the percentage of visitors that make purchases, to optimize staff shifts, or to monitor the costs of a shopping mall per visitor. Further, people counting systems may be used for anthropometric surveys. Further, the devices according to the present invention may be used in public transportation systems for automatically charging passengers depending on the length of transport. Further, the devices according to the present invention may be used in playgrounds for children, to recognize injured children or children engaged in dangerous activities, to allow additional interaction with playground toys, to ensure safe use of playground toys or the like.

Further the devices according to the present invention may be used in construction tools, such as a range meter that determines the distance to an object or to a wall, to assess whether a surface is planar, to align or objects or place objects in an ordered manner, or in inspection cameras for use in construction environments or the like.

Further, the devices according to the present invention may be applied in the field of sports and exercising, such as for training, remote instructions or competition purposes. Specifically, the devices according to the present invention may be applied in the fields of dancing, aerobic, football, soccer, basketball, baseball, cricket, hockey, track and field, swimming, polo, handball, volleyball, rugby, sumo, judo, fencing, boxing, golf, car racing, laser tag, battlefield simulation etc. The devices according to the present invention can be used to detect the position of a ball, a bat, a sword, motions, etc., both in sports and in games, such as to monitor the game, support the referee or for judgment, specifically automatic judgment, of specific situations in sports, such as for judging whether a point or a goal actually was made.

Further, the devices according to the present invention may be used in the field of auto racing or car driver training or car safety training or the like to determine the position of a car or the track of a car, or the deviation from a previous track or an ideal track or the like.

The devices according to the present invention may further be used to support a practice of musical instruments, in particular remote lessons, for example lessons of string instruments, such as fiddles, violins, violas, celli, basses, harps, guitars, banjos, or ukuleles, keyboard instruments, such as pianos, organs, keyboards, harpsichords, harmoniums, or accordions, and/or percussion instruments, such as drums, timpani, marimbas, xylophones, vibraphones, bongos, congas, timbales, djembes or tablas.

The devices according to the present invention further may be used in rehabilitation and physiotherapy, in order to encourage training and/or in order to survey and correct movements. Therein, the devices according to the present invention may also be applied for distance diagnostics.

Further, the devices according to the present invention may be applied in the field of machine vision. Thus, one or more of the devices according to the present invention may be used e.g. as a passive controlling unit for autonomous driving and or working of robots. In combination with moving robots, the devices according to the present invention may allow for autonomous movement and/or autonomous detection of failures in parts. The devices according to the present invention may also be used for manufacturing and safety surveillance, such as in order to avoid accidents including but not limited to collisions between robots, production parts and living beings. In robotics, the safe and direct interaction of humans and robots is often an issue, as robots may severely injure humans when they are not recognized. Devices according to the present invention may help robots to position objects and humans better and faster and allow a safe interaction. Given the passive nature of the devices according to the present invention, the devices according to the present invention may be advantageous over active devices and/or may be used complementary to existing solutions like radar, ultrasound, 2D cameras, IR detection etc. One particular advantage of the devices according to the present invention is the low likelihood of signal interference. Therefore multiple sensors can work at the same time in the same environment, without the risk of signal interference. Thus, the devices according to the present invention generally may be useful in highly automated production environments like e.g. but not limited to automotive, mining, steel, etc. The devices according to the present invention can also be used for quality control in production, e.g. in combination with other sensors like 2-D imaging, radar, ultrasound, IR etc., such as for quality control or other purposes. Further, the devices according to the present invention may be used for assessment of surface quality, such as for surveying the surface evenness of a product or the adherence to specified dimensions, from the range of micrometers to the range of meters. Other quality control applications are feasible. In a manufacturing environment, the devices according to the present invention are especially useful for processing natural products such as food or wood, with a complex 3-dimensional structure to avoid large amounts of waste material. Further, devices according to the present invention may be used to monitor the filling level of tanks, silos etc. Further, devices according to the present invention may be used to inspect complex products for missing parts, incomplete parts, loose parts, low quality parts, or the like, such as in automatic optical inspection, such as of printed circuit boards, inspection of assemblies or sub-assemblies, verification of engineered components, engine part inspections, wood quality inspection, label inspections, inspection of medical devices, inspection of product orientations, packaging inspections, food pack inspections, or the like.

Further, the devices according to the present invention may be used in vehicles, trains, airplanes, ships, spacecraft and other traffic applications. Thus, besides the applications mentioned above in the context of traffic applications, passive tracking systems for aircraft, vehicles and the like may be named. The use of at least one device according to the present invention, such as at least one detector according to the present invention, for monitoring the speed and/or the direction of moving objects is feasible. Specifically, the tracking of fast moving objects on land, sea and in the air including space may be named. The at least one device according to the present invention, such as the at least one detector according to the present invention, specifically may be mounted on a still-standing and/or on a moving device. An output signal of the at least one device according to the present invention can be combined e.g. with a guiding mechanism for autonomous or guided movement of another object. Thus, applications for avoiding collisions or for enabling collisions between the tracked and the steered object are feasible. The devices according to the present invention generally are useful and advantageous due to the low calculation power required, the instant response and due to the passive nature of the detection system which generally is more difficult to detect and to disturb as compared to active systems, like e.g. radar. The devices according to the present invention are particularly useful but not limited to e.g. speed control and air traffic control devices. Further, the devices according to the present invention may be used in automated tolling systems for road charges.

The devices according to the present invention generally may be used in passive applications. Passive applications include guidance for ships in harbors or in dangerous areas, and for aircraft when landing or starting. Wherein, fixed, known active targets may be used for precise guidance. The same can be used for vehicles driving on dangerous but well defined routes, such as mining vehicles. Further, the devices according to the present invention may be used to detect rapidly approaching objects, such as cars, trains, flying objects, animals, or the like. Further, the devices according to the present invention can be used for detecting velocities or accelerations of objects, or to predict the movement of an object by tracking one or more of its position, speed, and/or acceleration depending on time.

Further, as outlined above, the devices according to the present invention may be used in the field of gaming. Thus, the devices according to the present invention can be passive for use with multiple objects of the same or of different size, color, shape, etc., such as for movement detection in combination with software that incorporates the movement into its content. In particular, applications are feasible in implementing movements into graphical output. Further, applications of the devices according to the present invention for giving commands are feasible, such as by using one or more of the devices according to the present invention for gesture or facial recognition. The devices according to the present invention may be combined with an active system in order to work under e.g. low light conditions or in other situations in which enhancement of the surrounding conditions is required. Additionally or alternatively, a combination of one or more devices according to the present invention with one or more IR or VIS light sources is possible. A combination of a detector according to the present invention with special devices is also possible, which can be distinguished easily by the system and its software, e.g. and not limited to, a special color, shape, relative position to other devices, speed of movement, light, frequency used to modulate light sources on the device, surface properties, material used, reflection properties, transparency degree, absorption characteristics, etc. The device can, amongst other possibilities, resemble a stick, a racquet, a club, a gun, a knife, a wheel, a ring, a steering wheel, a bottle, a ball, a glass, a vase, a spoon, a fork, a cube, a dice, a figure, a puppet, a teddy, a beaker, a pedal, a switch, a glove, jewelry, a musical instrument or an auxiliary device for playing a musical instrument, such as a plectrum, a drumstick or the like. Other options are feasible.

Further, the devices according to the present invention may be used to detect and or track objects that emit light by themselves, such as due to high temperature or further light emission processes. The light emitting part may be an exhaust stream or the like. Further, the devices according to the present invention may be used to track reflecting objects and analyze the rotation or orientation of these objects.

Further, the devices according to the present invention generally may be used in the field of building, construction and cartography. Thus, generally, one or more devices according to the present invention may be used in order to measure and/or monitor environmental areas, e.g. countryside or buildings. Therein, one or more devices according to the present invention may be combined with other methods and devices or can be used solely in order to monitor progress and accuracy of building projects, changing objects, houses, etc. The devices according to the present invention can be used for generating three-dimensional models of scanned environments, in order to construct maps of rooms, streets, houses, communities or landscapes, both from ground or from air. Potential fields of application may be construction, cartography, real estate management, land surveying or the like. As an example, the devices according to the present invention may be used in multicopters to monitor buildings, agricultural production environments such as fields, production plants, or landscapes, to support rescue operations, or to find or monitor one or more persons or animals, or the like.

Further, the devices according to the present invention may be used within an interconnecting network of home appliances such as CHAIN (Cedec Home Appliances Interoperating Network) to interconnect, automate, and control basic appliance-related services in a home, e.g. energy or load management, remote diagnostics, pet related appliances, child related appliances, child surveillance, appliances related surveillance, support or service to elderly or ill persons, home security and/or surveillance, remote control of appliance operation, and automatic maintenance support. Further, the devices according to the present invention may be used in heating or cooling systems such as an air-conditioning system, to locate which part of the room should be brought to a certain temperature or humidity, especially depending on the location of one or more persons. Further, the devices according to the present invention may be used in domestic robots, such as service or autonomous robots which may be used for household chores. The devices according to the present invention may be used for a number of different purposes, such as to avoid collisions or to map the environment, but also to identify a user, to personalize the robot's performance for a given user, for security purposes, or for gesture or facial recognition. As an example, the devices according to the present invention may be used in robotic vacuum cleaners, floor-washing robots, dry-sweeping robots, ironing robots for ironing clothes, animal litter robots, such as cat litter robots, security robots that detect intruders, robotic lawn mowers, automated pool cleaners, rain gutter cleaning robots, window washing robots, toy robots, telepresence robots, social robots providing company to less mobile people, or robots translating and speech to sign language or sign language to speech. In the context of less mobile people, such as elderly persons, household robots with the devices according to the present invention may be used for picking up objects, transporting objects, and interacting with the objects and the user in a safe way. Further the devices according to the present invention may be used in robots operating with hazardous materials or objects or in dangerous environments. As a non-limiting example, the devices according to the present invention may be used in robots or unmanned remote-controlled vehicles to operate with hazardous materials such as chemicals or radioactive materials especially after disasters, or with other hazardous or potentially hazardous objects such as mines, unexploded arms, or the like, or to operate in or to investigate insecure environments such as near burning objects or post disaster areas.

Further, the devices according to the present invention may be used in household, mobile or entertainment devices, such as a refrigerator, a microwave, a washing machine, a window blind or shutter, a household alarm, an air condition devices, a heating device, a television, an audio device, a smart watch, a mobile phone, a phone, a dishwasher, a stove or the like, to detect the presence of a person, to monitor the contents or function of the device, or to interact with the person and/or share information about the person with further household, mobile or entertainment devices.

The devices according to the present invention may further be used in agriculture, for example to detect and sort out vermin, weeds, and/or infected crop plants, fully or in parts, wherein crop plants may be infected by fungus or insects. Further, for harvesting crops, the devices according to the present invention may be used to detect animals, such as deer, which may otherwise be harmed by harvesting devices. Further, the devices according to the present invention may be used to monitor the growth of plants in a field or greenhouse, in particular to adjust the amount of water or fertilizer or crop protection products for a given region in the field or greenhouse or even for a given plant. Further, in agricultural biotechnology, the devices according to the present invention may be used to monitor the size and shape of plants.

Further, the devices according to the present invention may be combined with sensors to detect chemicals or pollutants, electronic nose chips, microbe sensor chips to detect bacteria or viruses or the like, Geiger counters, tactile sensors, heat sensors, or the like. This may for example be used in constructing smart robots which are configured for handling dangerous or difficult tasks, such as in treating highly infectious patients, handling or removing highly dangerous substances, cleaning highly polluted areas, such as highly radioactive areas or chemical spills, or for pest control in agriculture.

One or more devices according to the present invention can further be used for scanning of objects, such as in combination with CAD or similar software, such as for additive manufacturing and/or 3D printing. Therein, use may be made of the high dimensional accuracy of the devices according to the present invention, e.g. in x-, y- or z-direction or in any arbitrary combination of these directions, such as simultaneously. Further, the devices according to the present invention may be used in inspections and maintenance, such as pipeline inspection gauges. Further, in a production environment, the devices according to the present invention may be used to work with objects of a badly defined shape such as naturally grown objects, such as sorting vegetables or other natural products by shape or size or cutting products such as meat or objects that are manufactured with a precision that is lower than the precision needed for a processing step.

Further the devices according to the present invention may be used in local navigation systems to allow autonomously or partially autonomously moving vehicles or multicopters or the like through an indoor or outdoor space. A non-limiting example may comprise vehicles moving through an automated storage for picking up objects and placing them at a different location. Indoor navigation may further be used in shopping malls, retail stores, museums, airports, or train stations, to track the location of mobile goods, mobile devices, baggage, customers or employees, or to supply users with a location specific information, such as the current position on a map, or information on goods sold, or the like.

Further, the devices according to the present invention may be used to ensure safe driving of motorcycles such as driving assistance for motorcycles by monitoring speed, inclination, upcoming obstacles, unevenness of the road, or curves or the like. Further, the devices according to the present invention may be used in trains or trams to avoid collisions.

Further, the devices according to the present invention may be used in handheld devices, such as for scanning packaging or parcels to optimize a logistics process. Further, the devices according to the present invention may be used in further handheld devices such as personal shopping devices, RFID-readers, handheld devices for use in hospitals or health environments such as for medical use or to obtain, exchange or record patient or patient health related information, smart badges for retail or health environments, or the like.

As outlined above, the devices according to the present invention may further be used in manufacturing, quality control or identification applications, such as in product identification or size identification (such as for finding an optimal place or package, for reducing waste etc.). Further, the devices according to the present invention may be used in logistics applications. Thus, the devices according to the present invention may be used for optimized loading or packing containers or vehicles. Further, the devices according to the present invention may be used for monitoring or controlling of surface damages in the field of manufacturing, for monitoring or controlling rental objects such as rental vehicles, and/or for insurance applications, such as for assessment of damages. Further, the devices according to the present invention may be used for identifying a size of material, object or tools, such as for optimal material handling, especially in combination with robots. Further, the devices according to the present invention may be used for process control in production, e.g. for observing filling level of tanks. Further, the devices according to the present invention may be used for maintenance of production assets like, but not limited to, tanks, pipes, reactors, tools etc. Further, the devices according to the present invention may be used for analyzing 3D-quality marks. Further, the devices according to the present invention may be used in manufacturing tailor-made goods such as tooth inlays, dental braces, prosthesis, clothes or the like. The devices according to the present invention may also be combined with one or more 3D-printers for rapid prototyping, 3D-copying or the like. Further, the devices according to the present invention may be used for detecting the shape of one or more articles, such as for anti-product piracy and for anti-counterfeiting purposes.

Thus, specifically, the present application may be applied in the field of photography. Thus, the detector may be part of a photographic device, specifically of a digital camera. Specifically, the detector may be used for 3D photography, specifically for digital 3D photography. Thus, the detector may form a digital 3D camera or may be part of a digital 3D camera. As used herein, the term photography generally refers to the technology of acquiring image information of at least one object. As further used herein, a camera generally is a device adapted for performing photography. As further used herein, the term digital photography generally refers to the technology of acquiring image information of at least one object by using a plurality of light-sensitive elements adapted to generate electrical signals indicating an intensity and/or color of illumination, preferably digital electrical signals. As further used herein, the term 3D photography generally refers to the technology of acquiring image information of at least one object in three spatial dimensions. Accordingly, a 3D camera is a device adapted for performing 3D photography. The camera generally may be adapted for acquiring a single image, such as a single 3D image, or may be adapted for acquiring a plurality of images, such as a sequence of images. Thus, the camera may also be a video camera adapted for video applications, such as for acquiring digital video sequences.

Thus, generally, the present invention further refers to a camera, specifically a digital camera, more specifically a 3D camera or digital 3D camera, for imaging at least one object. As outlined above, the term imaging, as used herein, generally refers to acquiring image information of at least one object. The camera comprises at least one detector according to the present invention. The camera, as outlined above, may be adapted for acquiring a single image or for acquiring a plurality of images, such as image sequence, preferably for acquiring digital video sequences. Thus, as an example, the camera may be or may comprise a video camera. In the latter case, the camera preferably comprises a data memory for storing the image sequence.

As used within the present invention, the expression “position” generally refers to at least one item of information regarding one or more of an absolute position and an orientation of one or more points of the object. Thus, specifically, the position may be determined in a coordinate system of the detector, such as in a Cartesian coordinate system. Additionally or alternatively, however, other types of coordinate systems may be used, such as polar coordinate systems and/or spherical coordinate systems.

As outlined above and as will be outlined in further detail below, the present invention preferably may be applied in the field of human-machine interfaces, in the field of sports and/or in the field of computer games. Thus, preferably, the object may be selected from the group consisting of: an article of sports equipment, preferably an article selected from the group consisting of a racket, a club, a bat, an article of clothing, a hat, a shoe. Other embodiments are feasible.

As used herein, the object generally may be an arbitrary object, chosen from a living object and a non-living object. Thus, as an example, the at least one object may comprise one or more articles and/or one or more parts of an article. Additionally or alternatively, the object may be or may comprise one or more living beings and/or one or more parts thereof, such as one or more body parts of a human being, e.g. a user, and/or an animal.

With regard to the coordinate system for determining the position of the object, which may be a coordinate system of the detector, the detector may constitute a coordinate system in which an optical axis of the detector forms the z-axis and in which, additionally, an x-axis and a y-axis may be provided which are perpendicular to the z-axis and which are perpendicular to each other. As an example, the detector and/or a part of the detector may rest at a specific point in this coordinate system, such as at the origin of this coordinate system. In this coordinate system, a direction parallel or antiparallel to the z-axis may be regarded as a longitudinal direction, and a coordinate along the z-axis may be considered a longitudinal coordinate. An arbitrary direction perpendicular to the longitudinal direction may be considered a transversal direction, and an x- and/or y-coordinate may be considered a transversal coordinate.

Alternatively, other types of coordinate systems may be used. Thus, as an example, a polar coordinate system may be used in which the optical axis forms a z-axis and in which a distance from the z-axis and a polar angle may be used as additional coordinates. Again, a direction parallel or antiparallel to the z-axis may be considered a longitudinal direction, and a coordinate along the z-axis may be considered a longitudinal coordinate. Any direction perpendicular to the z-axis may be considered a transversal direction, and the polar coordinate and/or the polar angle may be considered a transversal coordinate.

The detector may be a device configured for providing at least one item of information on the position of the at least one object and/or a part thereof. Thus, the position may refer to an item of information fully describing the position of the object or a part thereof, preferably in the coordinate system of the detector, or may refer to a partial information, which only partially describes the position. The detector generally may be a device adapted for detecting light beams, such as the light beams propagating from the beacon devices towards the detector.

The evaluation device and the detector may fully or partially be integrated into a single device. Thus, generally, the evaluation device also may form part of the detector. Alternatively, the evaluation device and the detector may fully or partially be embodied as separate devices. The detector may comprise further components.

The detector may be a stationary device or a mobile device. Further, the detector may be a stand-alone device or may form part of another device, such as a computer, a vehicle or any other device. Further, the detector may be a hand-held device. Other embodiments of the detector are feasible.

The detector specifically may be used to record a light-field behind a lens or lens system of the detector, comparable to a plenoptic or light-field camera. Thus, specifically, the detector may be embodied as a light-field camera adapted for acquiring images in multiple focal planes, such as simultaneously. The term light-field, as used herein, generally refers to the spatial light propagation of light inside the detector such as inside camera. The detector according to the present invention, specifically having a layer setup of optical sensors, may have the capability of directly recording a light-field within the detector or camera, such as behind a lens. The plurality of sensors may record images at different distances from the lens. Using, e.g., convolution-based algorithms such as “depth from focus” or “depth from defocus”, the propagation direction, focus points, and spread of the light behind the lens can be modeled. From the modeled propagation of light behind the lens, images at various distances to the lens can be extracted, the depth of field can be optimized, pictures that are in focus at various distances can be extracted, or distances of objects can be calculated. Further information may be extracted.

Once the light propagation inside the detector, such as behind a lens of the detector, is modeled and/or recorded, this knowledge of light propagation provides a large number of advantages. Thus, the light-field may be recorded in terms of beam parameters for one or more light beams of a scene captured by the detector. As an example, for each light beam recorded, two or more beam parameters may be recorded, such as one or more Gaussian beam parameters, e.g. a beam waist, a minimum beam waist as a focal point, a Rayleigh length, or other beam parameters. Several representations of light beams may be used and beam parameters may be chosen accordingly.

This knowledge of light propagation, as an example, allows for slightly modifying the observer position after recording an image stack using image processing techniques. In a single image, an object may be hidden behind another object and is not visible. However, if the light scattered by the hidden object reaches the lens and through the lens one or more of the sensors, the object may be made visible, by changing the distance to the lens and/or the image plane relative to the optical axis, or even using non-planar image planes. The change of the observer position may be compared to looking at a hologram, in which changing the observer position slightly changes the image.

The knowledge of light propagation inside the detector, such as by modeling the light propagation behind the lens, may further allow for storing the image information in a more compact way as compared to conventional technology of storing each image recorded by each individual optical sensor. The memory demand of the light propagation scales with the number of modeled light beams times the number of parameters per light beam. Typical model functions for light beams may be Gaussians, Lorentzians, Bessel functions, especially spherical Bessel functions, other functions typically used for describing diffraction effects in physics, or typical spread functions used in depth from defocus techniques such as point spread functions, line spread functions or edge spread functions.

The use of several optical sensors further allows for correcting lens errors in an image processing step after recording the images. Optical instruments often become expensive and challenging in construction, when lens errors need to be corrected. These are especially problematic in microscopes and telescopes. In microscopes, a typical lens error is that rays of varying distance to the optical axis are distorted differently (spherical aberration). In telescopes, varying the focus may occur from differing temperatures in the atmosphere. Static errors such as spherical aberration or further errors from production may be corrected by determining the errors in a calibration step and then using a fixed image processing such as fixed set of pixels and sensor, or more involved processing techniques using light propagation information. In cases in which lens errors are strongly time-dependent, i.e. dependent on weather conditions in telescopes, the lens errors may be corrected by using the light propagation behind the lens, calculating extended depth of field images, using depth from focus techniques, and others.

As outlined above, the detector according to the present invention may further allow for color detection. For color detection in stacks of several optical sensors, the single stacks may have optical sensors that have different absorption properties, equal or similar to the so-called Bayer pattern, and color information may be obtained by interpolation techniques. A further method is to use sensors of alternating color, wherein different sensors in the stack may record different colors. In a Bayer pattern, color may be interpolated between same-color pixels. In a stack of sensors, the image information such as color and brightness, etc., can also be obtained by interpolation techniques.

The evaluation device may be or may comprise one or more integrated circuits, such as one or more application-specific integrated circuits (ASICs), and/or one or more digital signal processors (DSPs), and/or one or more field programmable gate arrays (FPGAs), and/or one or more data processing devices, such as one or more computers, preferably one or more microcomputers and/or microcontrollers. Additional components may be comprised, such as one or more preprocessing devices and/or data acquisition devices, such as one or more devices for receiving and/or preprocessing of the sensor signals, such as one or more AD-converters and/or one or more filters and/or more phase-sensitive electronic elements, particularly based on a lock-in measuring technique. Further, the evaluation device may comprise one or more measurement devices, such as one or more measurement devices for measuring electrical currents and/or electrical voltages. Further, the evaluation device may comprise one or more data storage devices. Further, the evaluation device may comprise one or more interfaces, such as one or more wireless interfaces and/or one or more wire-bound interfaces.

The at least one evaluation device may be adapted to perform at least one computer program, such as at least one computer program adapted for performing or supporting one or more or even all of the method steps of the method according to the present invention. As an example, one or more algorithms may be implemented which, by using the sensor signals as input variables, may determine the position of the object.

The evaluation device can be connected to or may comprise at least one further data processing device that may be used for one or more of displaying, visualizing, analyzing, distributing, communicating or further processing of information, such as information obtained by the optical sensors and/or by the evaluation device. The data processing device, as an example, may be connected or incorporate at least one of a display, a projector, a monitor, an LCD, a TFT, a loudspeaker, a multichannel sound system, an LED pattern, or a further visualization device. It may further be connected or incorporate at least one of a communication device or communication interface, a connector or a port, capable of sending encrypted or unencrypted information using one or more of email, text messages, telephone, Bluetooth, Wi-Fi, infrared or internet interfaces, ports or connections. It may further be connected or incorporate at least one of a processor, a graphics processor, a CPU, an Open Multimedia Applications Platform (OMAP™), an integrated circuit, a system on a chip such as products from the Apple A series or the Samsung S3C2 series, a microcontroller or microprocessor, one or more memory blocks such as ROM, RAM, EEPROM, or flash memory, timing sources such as oscillators or phase-locked loops, counter-timers, real-time timers, or power-on reset generators, voltage regulators, power management circuits, or DMA controllers. Individual units may further be connected by buses such as AMBA buses.

The evaluation device and/or the data processing device may be connected by or have further external interfaces or ports such as one or more of serial or parallel interfaces or ports, USB, Centronics Port, FireWire, HDMI, Ethernet, Bluetooth, RFID, Wi-Fi, USART, or SPI, or analogue interfaces or ports such as one or more of ADCs or DACs, or standardized interfaces or ports to further devices such as a 2D-camera device using an RGB-interface such as CameraLink. The evaluation device and/or the data processing device may further be connected by one or more of interprocessor interfaces or ports, FPGA-FPGA-interfaces, or serial or parallel interfaces ports. The evaluation device and the data processing device may further be connected to one or more of an optical disc drive, a CD-RW drive, a DVD+RW drive, a flash drive, a memory card, a disk drive, a hard disk drive, a solid state disk or a solid state hard disk.

The evaluation device and/or the data processing device may be connected by or have one or more further external connectors such as one or more of phone connectors, RCA connectors, VGA connectors, hermaphrodite connectors, USB connectors, HDMI connectors, 8P8C connectors, BCN connectors, IEC 60320 C14 connectors, optical fiber connectors, D-subminiature connectors, RF connectors, coaxial connectors, SCART connectors, XLR connectors, and/or may incorporate at least one suitable socket for one or more of these connectors.

Possible embodiments of a single device incorporating one or more of the detectors according to the present invention, the evaluation device or the data processing device, such as incorporating one or more of the optical sensors, optical systems, evaluation device, communication device, data processing device, interfaces, system on a chip, display devices, or further electronic devices, are: mobile phones, personal computers, tablet PCs, televisions, game consoles or further entertainment devices. In a further embodiment, the 3D-camera functionality which will be outlined in further detail below may be integrated in devices that are available with conventional 2D-digital cameras, without a noticeable difference in the housing or appearance of the device, where the noticeable difference for the user may only be the functionality of obtaining and or processing 3D information.

Specifically, an embodiment incorporating the detector and/or a part thereof such as the evaluation device and/or the data processing device may be: a mobile phone incorporating a display device, a data processing device, the optical sensors, optionally the sensor optics, and the evaluation device, for the functionality of a 3D camera. The detector according to the present invention specifically may be suitable for integration in entertainment devices and/or communication devices such as a mobile phone.

A further embodiment of the present invention may be an incorporation of the detector or a part thereof such as the evaluation device and/or the data processing device in a device for use in automotive, for use in autonomous driving or for use in car safety systems such as Daimler's Intelligent Drive system, wherein, as an example, a device incorporating one or more of the optical sensors, optionally one or more optical systems, the evaluation device, optionally a communication device, optionally a data processing device, optionally one or more interfaces, optionally a system on a chip, optionally one or more display devices, or optionally further electronic devices may be part of a vehicle, a car, a truck, a train, a bicycle, an airplane, a ship, a motorcycle. In automotive applications, the integration of the device into the automotive design may necessitate the integration of the optical sensors, optionally optics, or device at minimal visibility from the exterior or interior. The detector or a part thereof such as the evaluation device and/or the data processing device may be especially suitable for such integration into automotive design.

As used herein, the term light generally refers to electromagnetic radiation in one or more of the visible spectral range, the ultraviolet spectral range and the infrared spectral range. Therein, the term visible spectral range generally refers to a spectral range of 380 nm to 780 nm. The term infrared spectral range generally refers to electromagnetic radiation in the range of 780 nm to 1 mm, preferably in the range of 780 nm to 3.0 micrometers. The term ultraviolet spectral range generally refers to electromagnetic radiation in the range of 1 nm to 380 nm, preferably in the range of 100 nm to 380 nm. Preferably, light as used within the present invention is visible light, i.e. light in the visible spectral range.

The term light beam generally refers to an amount of light emitted and/or reflected into a specific direction. Thus, the light beam may be a bundle of the light rays having a predetermined extension in a direction perpendicular to a direction of propagation of the light beam. Preferably, the light beams may be or may comprise one or more Gaussian light beams which may be characterized by one or more Gaussian beam parameters, such as one or more of a beam waist, a Rayleigh-length or any other beam parameter or combination of beam parameters suited to characterize a development of a beam diameter and/or a beam propagation in space.

As outlined above, the present invention further relates to a human-machine interface for exchanging at least one item of information between a user and a machine. The human-machine interface as proposed may make use of the fact that the above-mentioned detector in one or more of the embodiments mentioned above or as mentioned in further detail below may be used by one or more users for providing information and/or commands to a machine. Thus, preferably, the human-machine interface may be used for inputting control commands.

Generally, as used herein, the at least one position of the user may imply one or more items of information on a position of the user as a whole and/or one of or more body parts of the user. Thus, preferably, the position of the user may imply one or more items of information on a position of the user as provided by the evaluation device of the detector. The user, a body part of the user or a plurality of body parts of the user may be regarded as one or more objects the position of which may be detected by the at least one detector device. Therein, precisely one detector may be provided, or a combination of a plurality of detectors may be provided. As an example, a plurality of detectors may be provided for determining positions of a plurality of body parts of the user and/or for determining a position of at least one body part of the user.

The detector according to the present invention may further be combined with one or more other types of sensors or detectors. Thus, the detector may further comprise at least one additional detector. The at least one additional detector may be adapted for detecting at least one parameter, such as at least one of: a parameter of a surrounding environment, such as a temperature and/or a brightness of a surrounding environment; a parameter regarding a position and/or orientation of the detector; a parameter specifying a state of the object to be detected, such as a position of the object, e.g. an absolute position of the object and/or an orientation of the object in space. Thus, generally, the principles of the present invention may be combined with other measurement principles in order to gain additional information and/or in order to verify measurement results or reduce measurement errors or noise.

Specifically, the detector according to the present invention may further comprise at least one time-of-flight (ToF) detector adapted for detecting at least one distance between the at least one object and the detector by performing at least one time-of-flight measurement. As used herein, a time-of-flight measurement generally refers to a measurement based on a time a signal needs for propagating between two objects or from one object to a second object and back. In the present case, the signal specifically may be one or more of an acoustic signal or an electromagnetic signal such as a light signal. A time-of-flight detector consequently refers to a detector adapted for performing a time-of-flight measurement. Time-of-flight measurements are well-known in various fields of technology such as in commercially available distance measurement devices or in commercially available flow meters, such as ultrasonic flow meters. Time-of-flight detectors even may be embodied as time-of-flight cameras. These types of cameras are commercially available as range-imaging camera systems, capable of resolving distances between objects based on the known speed of light.

Presently available ToF detectors generally are based on the use of a pulsed signal, optionally in combination with one or more light sensors such as CMOS-sensors. A sensor signal produced by the light sensor may be integrated. The integration may start at two different points in time. The distance may be calculated from the relative signal intensity between the two integration results.

Further, as outlined above, ToF cameras are known and may generally be used, also in the context of the present invention. These ToF cameras may contain pixelated light sensors. However, since each pixel generally has to allow for performing two integrations, the pixel construction generally is more complex and the resolutions of commercially available ToF cameras are rather low (typically 200×200 pixels). Distances below ˜40 cm and above several meters typically are difficult or impossible to detect. Furthermore, the periodicity of the pulses leads to ambiguous distances, as only the relative shift of the pulses within one period is measured.

ToF detectors, as standalone devices, typically suffer from a variety of shortcomings and technical challenges. Thus, in general, ToF detectors and, more specifically, ToF cameras suffer from rain and other transparent objects in the light path, since the pulses might be reflected too early, objects behind the raindrop are hidden, or in partial reflections the integration will lead to erroneous results. Further, in order to avoid errors in the measurements and in order to allow for a clear distinction of the pulses, low light conditions are preferred for ToF-measurements. Bright light such as bright sunlight can make a ToF-measurement impossible. Further, the energy consumption of typical ToF cameras is rather high, since pulses must be bright enough to be back-reflected and still be detectable by the camera. The brightness of the pulses, however, may be harmful for eyes or other sensors or may cause measurement errors when two or more ToF measurements interfere with each other. In summary, current ToF detectors and, specifically, current ToF-cameras suffer from several disadvantages such as low resolution, ambiguities in the distance measurement, limited range of use, limited light conditions, sensitivity towards transparent objects in the light path, sensitivity towards weather conditions and high energy consumption. These technical challenges generally lower the aptitude of present ToF cameras for daily applications such as for safety applications in cars, cameras for daily use or human-machine-interfaces, specifically for use in gaming applications.

In combination with the detector according to the present invention, the advantages and capabilities of both systems may be combined in a fruitful way. Thus, the detector may provide advantages at bright light conditions, while the ToF detector generally provides better results at low-light conditions. A combined device, i.e. a detector according to the present invention further including at least one ToF detector, therefore provides increased tolerance with regard to light conditions as compared to both single systems. This is especially important for safety applications, such as in cars or other vehicles.

Specifically, the detector may be designed to use at least one ToF measurement for correcting at least one measurement performed by using the detector according to the present invention and vice versa. Further, the ambiguity of a ToF measurement may be resolved by using the detector.

The at least one optional ToF detector may be combined with basically any of the embodiments of the detector according to the present invention. Specifically, the at least one ToF detector which may be a single ToF detector or a ToF camera, may be combined with a single optical sensor or with a plurality of optical sensors such as a sensor stack. Further, the detector may also comprise one or more imaging devices such as one or more inorganic imaging devices like CCD chips and/or CMOS chips, preferably one or more full-color CCD chips or full-color CMOS chips. Additionally or alternatively, the detector may further comprise one or more thermographic cameras.

As outlined above, the human-machine interface may comprise a plurality of beacon devices which are adapted to be at least one of directly or indirectly attached to the user and held by the user. Thus, the beacon devices each may independently be attached to the user by any suitable means, such as by an appropriate fixing device. Additionally or alternatively, the user may hold and/or carry the at least one beacon device or one or more of the beacon devices in his or her hands and/or by wearing the at least one beacon device and/or a garment containing the beacon device on a body part.

The beacon device generally may be an arbitrary device which may be detected by the at least one detector and/or which facilitates detection by the at least one detector. Thus, as outlined above or as will be outlined in further detail below, the beacon device may be an active beacon device adapted for generating the at least one light beam to be detected by the detector, such as by having one or more illumination sources for generating the at least one light beam. Additionally or alternatively, the beacon device may fully or partially be designed as a passive beacon device, such as by providing one or more reflective elements adapted to reflect a light beam generated by a separate illumination source. The at least one beacon device may permanently or temporarily be attached to the user in a direct or indirect way and/or may be carried or held by the user. The attachment may take place by using one or more attachment means and/or by the user himself or herself, such as by the user holding the at least one beacon device by hand and/or by the user wearing the beacon device.

Additionally or alternatively, the beacon devices may be at least one of attached to an object and integrated into an object held by the user, which, in the sense of the present invention, shall be included into the meaning of the option of the user holding the beacon devices. Thus, as will be outlined in further detail below, the beacon devices may be attached to or integrated into a control element which may be part of the human-machine interface and which may be held or carried by the user, and of which the orientation may be recognized by the detector device. Thus, generally, the present invention also refers to a detector system comprising at least one detector device according to the present invention and which, further, may comprise at least one object, wherein the beacon devices are one of attached to the object, held by the object and integrated into the object. As an example, the object preferably may form a control element, the orientation of which may be recognized by a user. Thus, the detector system may be part of the human-machine interface as outlined above or as outlined in further detail below. As an example, the user may handle the control element in a specific way in order to transmit one or more items of information to a machine, such as in order to transmit one or more commands to the machine.

Alternatively, the detector system may be used in other ways. Thus, as an example, the object of the detector system may be different from a user or a body part of the user and, as an example, may be an object which moves independently from the user. As an example, the detector system may be used for controlling apparatuses and/or industrial processes, such as manufacturing processes and/or robotics processes. Thus, as an example, the object may be a machine and/or a machine part, such as a robot arm, the orientation of which may be detected by using the detector system.

The human-machine interface may be adapted in such a way that the detector device generates at least one item of information on the position of the user or of at least one body part of the user. Specifically in case a manner of attachment of the at least one beacon device to the user is known, by evaluating the position of the at least one beacon device, at least one item of information on a position and/or an orientation of the user or of a body part of the user may be gained.

The beacon device preferably is one of a beacon device attachable to a body or a body part of the user and a beacon device which may be held by the user. As outlined above, the beacon device may fully or partially be designed as an active beacon device. Thus, the beacon device may comprise at least one illumination source adapted to generate at least one light beam to be transmitted to the detector, preferably at least one light beam having known beam properties. Additionally or alternatively, the beacon device may comprise at least one reflector adapted to reflect light generated by an illumination source, thereby generating a reflected light beam to be transmitted to the detector.

The object, which may form part of the detector system, may generally have an arbitrary shape. Preferably, the object being part of the detector system, as outlined above, may be a control element which may be handled by a user, such as manually. As an example, the control element may be or may comprise at least one element selected from the group consisting of: a glove, a jacket, a hat, shoes, trousers and a suit, a stick that may be held by hand, a bat, a club, a racket, a cane, a toy, such as a toy gun. Thus, as an example, the detector system may be part of the human-machine interface and/or of the entertainment device.

As used herein, an entertainment device is a device which may serve the purpose of leisure and/or entertainment of one or more users, in the following also referred to as one or more players. As an example, the entertainment device may serve the purpose of gaming, preferably computer gaming. Thus, the entertainment device may be implemented into a computer, a computer network or a computer system or may comprise a computer, a computer network or a computer system which runs one or more gaming software programs.

The entertainment device comprises at least one human-machine interface according to the present invention, such as according to one or more of the embodiments disclosed above and/or according to one or more of the embodiments disclosed below. The entertainment device is designed to enable at least one item of information to be input by a player by means of the human-machine interface. The at least one item of information may be transmitted to and/or may be used by a controller and/or a computer of the entertainment device.

The at least one item of information preferably may comprise at least one command adapted for influencing the course of a game. Thus, as an example, the at least one item of information may include at least one item of information on at least one orientation of the player and/or of one or more body parts of the player, thereby allowing for the player to simulate a specific position and/or orientation and/or action required for gaming. As an example, one or more of the following movements may be simulated and communicated to a controller and/or a computer of the entertainment device: dancing; running; jumping; swinging of a racket; swinging of a bat; swinging of a club; pointing of an object towards another object, such as pointing of a toy gun towards a target.

The entertainment device as a part or as a whole, preferably a controller and/or a computer of the entertainment device, is designed to vary the entertainment function in accordance with the information. Thus, as outlined above, a course of a game might be influenced in accordance with the at least one item of information. Thus, the entertainment device might include one or more controllers which might be separate from the evaluation device of the at least one detector and/or which might be fully or partially identical to the at least one evaluation device or which might even include the at least one evaluation device. Preferably, the at least one controller might include one or more data processing devices, such as one or more computers and/or microcontrollers.

As further used herein, a tracking system is a device which is adapted to gather information on a series of past positions of the at least one object and/or at least one part of the object. Additionally, the tracking system may be adapted to provide information on at least one predicted future position and/or orientation of the at least one object or the at least one part of the object. The tracking system may have at least one track controller, which may fully or partially be embodied as an electronic device, preferably as at least one data processing device, more preferably as at least one computer or microcontroller. Again, the at least one track controller may fully or partially comprise the at least one evaluation device and/or may be part of the at least one evaluation device and/or may fully or partially be identical to the at least one evaluation device.

The tracking system comprises at least one detector according to the present invention, such as at least one detector as disclosed in one or more of the embodiments listed above and/or as disclosed in one or more of the embodiments below. The tracking system further comprises at least one track controller. The track controller is adapted to track a series of positions of the object at specific points in time, such as by recording groups of data or data pairs, each group of data or data pair comprising at least one position information and at least one time information.

The tracking system may further comprise the at least one detector system according to the present invention. Thus, besides the at least one detector and the at least one evaluation device and the optional at least one beacon device, the tracking system may further comprise the object itself or a part of the object, such as at least one control element comprising the beacon devices or at least one beacon device, wherein the control element is directly or indirectly attachable to or integratable into the object to be tracked.

The tracking system may be adapted to initiate one or more actions of the tracking system itself and/or of one or more separate devices. For the latter purpose, the tracking system, preferably the track controller, may have one or more wireless and/or wire-bound interfaces and/or other types of control connections for initiating at least one action. Preferably, the at least one track controller may be adapted to initiate at least one action in accordance with at least one actual position of the object. As an example, the action may be selected from the group consisting of: a prediction of a future position of the object; pointing at least one device towards the object; pointing at least one device towards the detector; illuminating the object; illuminating the detector.

As an example of application of a tracking system, the tracking system may be used for continuously pointing at least one first object to at least one second object even though the first object and/or the second object might move. Potential examples, again, may be found in industrial applications, such as in robotics and/or for continuously working on an article even though the article is moving, such as during manufacturing in a manufacturing line or assembly line. Additionally or alternatively, the tracking system might be used for illumination purposes, such as for continuously illuminating the object by continuously pointing an illumination source to the object even though the object might be moving. Further applications might be found in communication systems, such as in order to continuously transmit information to a moving object by pointing a transmitter towards the moving object.

The detector, the detector system, the human machine interface, the entertainment device or the tracking system may further comprise at least one illumination source or may be used in conjunction with at least one illumination source. Specifically, the at least one illumination source may be or may comprise at least one structured or patterned illumination source. The use of a structured illumination source may increase a resolution of the position detection of the object and/or may increase a contrast.

The proposed devices and methods provide a large number of advantages over known detectors of this kind. Locating two PIN-photodiodes in one layer setup of one longitudinal optical sensor allows miniaturization and determining a position of at least one object reliably and without ambiguities. By using a transparent layer setup of the longitudinal optical sensor, it is possible to locate a transversal optical sensor, in particular a conventional imaging device and/or PSD, within the same beam path, wherein the transversal is arranged behind the longitudinal optical sensor. In addition, by using a (semi-)transparent PSD device, it is possible to locate the transversal optical sensor and the longitudinal optical sensor within the same beam path, wherein the transversal optical sensor may be located in front of at least one longitudinal optical sensor and/or wherein the longitudinal optical sensor and the transversal optical sensor may be designed monolithic within one layer setup. As a result, such a combination of the (semi-)transparent PSD device with the FiP sensor may, particularly, be suited for providing detectors which may realize 3D-sensing concepts exhibiting an improved performance with respect to one or more of miniaturization, robustness, determination time, determination accuracy, and cost effectiveness.

Overall, in the context of the present invention, the following embodiments are regarded as preferred:

### Embodiment 1

A detector for determining a position of at least one object, the detector comprising:
at least one longitudinal optical sensor for determining a longitudinal position of at least one light beam traveling from the object to the detector, the longitudinal optical sensor having a layer setup, wherein the longitudinal optical sensor comprises at least two p-type semiconductor layers, at least two n-type semiconductor layers, and at least three individual electrode layers,
   wherein the p-type semiconductor layers and the n-type semiconductor layers form at least two individual PN structures, wherein each of the PN structures is located between at least two of the electrode layers, thereby forming at least two photodiodes,
   wherein each of the two photodiodes has at least one longitudinal sensor region, wherein the longitudinal optical sensor is designed to generate at least two longitudinal sensor signals in a manner dependent on an illumination of the longitudinal sensor region by the light beam, wherein the longitudinal sensor signals, given the same total power of the illumination, are dependent on a beam cross-section of the light beam in the longitudinal sensor region; and
at least one evaluation device, wherein the evaluation device is configured to determine at least one longitudinal coordinate of the object by evaluating the longitudinal sensor signals.

### Embodiment 2

The detector according to the preceding embodiment, wherein the longitudinal optical sensor comprises at least one intrinsic semiconductor layer, wherein the intrinsic semiconductor layer is located between one of the p-type semiconductor layers and one of the n-type semiconductor layers, thereby forming at least one PIN structure.

### Embodiment 3

The detector according to the preceding embodiment, wherein the longitudinal optical sensor comprises at least two intrinsic semiconductor layers, wherein each of the intrinsic semiconductor layers is located between one of the p-type semiconductor layers and one of the n-type semiconductor layers, thereby forming at least two individual PIN structures.

### Embodiment 4

The detector according to any one of the two preceding embodiments, wherein one or more of the intrinsic semiconductor layer, the p-type semiconductor layer and the n-type semiconductor layer comprise one or more of amorphous silicon, an alloy comprising amorphous silicon, microcrystalline silicon, germanium (Ge), copper indium sulfide (CIS), copper indium gallium selenide (CIGS), copper zinc tin sulfide (CZTS), copper zinc tin selenide (CZTSe), copper-zinc-tin sulfur-selenium chalcogenide (CZTSSe), cadmium telluride (CdTe), mercury cadmium telluride (HgCdTe), indium arsenide (InAs), indium gallium arsenide (InGaAs), indium antimonide (InSb), an organic-inorganic halide perovskite, and solid solutions and/or doped variants thereof.

### Embodiment 5

The detector according to the preceding embodiment, wherein the alloy comprising amorphous silicon is an amorphous alloy comprising silicon and carbon or an amorphous alloy comprising silicon and germanium.

### Embodiment 6

The detector according to any one of the two preceding embodiments, wherein the amorphous silicon is passivated by using hydrogen.

### Embodiment 7

The detector according to any one of the five preceding embodiments, wherein the intrinsic semiconductor layer has a thickness of 100 nm to 300 nm, in particular from 150 to 200 nm.

### Embodiment 8

The detector according to any one of the preceding embodiments, wherein the longitudinal optical sensor is at least partially transparent.

### Embodiment 9

The detector according to the preceding embodiment, wherein the layer setup is adapted to be traversed by the incident light beam in an order in which the layers are arranged within the layer setup.

### Embodiment 10

The detector according to any one of the two preceding embodiments, wherein each of the layers in the layer setup is at least partially transparent or translucent.

### Embodiment 11

The detector according to any one of the three preceding embodiments, wherein each of the layers in the layer setup but the last layer in the setup to be traversed by the incident light beam is at least partially transparent or translucent.

### Embodiment 12

The detector according to any one of the preceding embodiments, wherein two adjacent PIN structures share one of the electrode layers as a common electrode layer.

### Embodiment 13

The detector according to any one of the preceding embodiments, wherein two adjacent electrode layers having the same polarity are separated from each other by an insulating layer.

### Embodiment 14

The detector according to the preceding embodiment, wherein the insulating layer comprises a layer of one of glass, quartz, or a transparent organic polymer.

### Embodiment 15

The detector according to any one of the preceding embodiments, wherein each of the photodiodes is configured to be addressed individually.

### Embodiment 16

The detector according to the preceding embodiment, wherein a first photodiode is designed to generate at least a first longitudinal sensor signal, and a second photodiode is designed to generate at least a second longitudinal sensor signal, wherein the evaluation device is adapted to determine the first longitudinal optical sensor signal and the second longitudinal sensor signal simultaneously.

### Embodiment 17

The detector according to any one of the preceding embodiments, wherein the electrode layers comprise electrically conductive material, wherein the electrode layers are at least partially transparent, wherein the electrode layers comprise transparent conductive oxide (TCO), in particular one or more of indium tin oxide (ITO), zinc oxide (ZnO), fluorine-doped tin oxide (FTO), aluminum-doped zinc oxide (AZO), antimony tin oxide (ATO).

### Embodiment 18

The detector according to any one of the preceding embodiments, wherein the longitudinal optical sensor comprises at least one spacer layer, wherein the spacer layer is designed to separate a first photodiode and a second photodiode.

### Embodiment 19

The detector according to any one of the preceding embodiments, wherein the detector further comprises at least one transversal optical sensor for determining at least one transversal position of the at least one light beam traveling from the object to the detector, wherein the transversal optical sensor is designed to generate at least one transversal sensor signal, wherein the evaluation device is further configured to determine at least one transversal coordinate of the object by evaluating the transversal sensor signal.

### Embodiment 20

The detector according to any one of the preceding embodiments, wherein the longitudinal optical sensor and the transversal optical sensor are arranged in a monolithic device.

### Embodiment 21

The detector according to the preceding embodiment, wherein the layer setup further comprises at least one layer adapted to act as a transversal optical sensor.

### Embodiment 22

The detector according to any one of the two preceding embodiments, wherein the layer adapted to act as a transversal optical sensor is intransparent and arranged as the last layer in the layer setup to be to be traversed by the incident light beam.

### Embodiment 23

The detector according to any one of the three preceding embodiments, wherein the layer adapted to act as a transversal optical sensor is at least partially transparent or translucent.

### Embodiment 24

The detector according to any one of the two preceding embodiments, wherein the layer adapted to act as transversal optical sensor is arranged as first layer in the setup to be traversed by the incident light beam.

### Embodiment 25

The detector according to any one of the preceding embodiments, wherein the detector is configured to detect at least two longitudinal sensor signals at respectively different modulation frequencies, wherein the evaluation device is configured to determine the longitudinal coordinates by evaluating the at least two longitudinal sensor signals.

### Embodiment 26

The detector according to any one of the preceding embodiments, wherein the detector is configured to detect at least two transversal sensor signals at respectively different modulation frequencies, wherein the evaluation device is configured to determine the transversal coordinates by evaluating the at least two transversal sensor signals.

### Embodiment 27

The detector according to any one of the preceding embodiments, wherein the light beam is a modulated light beam.

### Embodiment 28

The detector according to any one of the preceding embodiments, wherein the detector furthermore has at least one modulation device for modulating the illumination.

### Embodiment 29

The detector according to any one of the preceding embodiments, wherein the detector further comprises at least one transfer device, the transfer device being adapted to guide the light beam onto the optical sensor.

### Embodiment 30

The detector according to the preceding embodiment, wherein the transfer device comprises one or more of: at least one lens, preferably at least one focus-tunable lens; at least one beam deflection element, preferably at least one mirror; at least one beam splitting element, preferably at least one of a beam splitting cube or a beam splitting mirror; at least one multi-lens system.

### Embodiment 31

The detector according to any one of the preceding embodiments, wherein the longitudinal optical sensor is adapted to operate as FiP-device and at the same time as position-sensitive device, in particular as position-sensitive device adapted for one-dimensional position sensing.

### Embodiment 32

The detector according to the preceding embodiment, wherein the longitudinal optical sensor comprises two cells, wherein each cell comprises at least one PIN structure and/or PN structure and at least two electrode layers, wherein the two cells are rotated by 90° to each other such that one cell is adapted to determine a transversal coordinate x and the other cell is adapted to determine the transversal coordinate y.

### Embodiment 33

A detector system for determining a position of at least one object, the detector system comprising at least one detector according to any one of the preceding embodiments, the detector system further comprising at least one beacon device adapted to direct at least one light beam towards the detector, wherein the beacon device is at least one of attachable to the object, holdable by the object and integratable into the object.

### Embodiment 34

A human-machine interface for exchanging at least one item of information between a user and a machine, wherein the human-machine interface comprises at least one detector system according to the preceding embodiment, wherein the at least one beacon device is adapted to be at least one of directly or indirectly attached to the user and held by the user, wherein the human-machine interface is designed to determine at least one position of the user by means of the detector system, wherein the human-machine interface is designed to assign to the position at least one item of information.

### Embodiment 35

An entertainment device for carrying out at least one entertainment function, wherein the entertainment device comprises at least one human-machine interface according to the preceding embodiment, wherein the entertainment device is designed to enable at least one item of information to be input by a player by means of the human-machine interface, wherein the entertainment device is designed to vary the entertainment function in accordance with the information.

### Embodiment 36

A method for determining a position of at least one object, wherein in the method at least one detector according to any one of the preceding embodiments referring to a detector is used, the method comprising the following steps:
generating at least two longitudinal sensor signals by using at least one longitudinal optical sensor for determining a longitudinal position of at least one light beam traveling from the object to the detector, the longitudinal optical sensor having a layer setup, wherein the longitudinal optical sensor comprises at least two intrinsic semiconductor layers, at least two p-type semiconductor layers, at least two n-type semiconductor layers, and at least three individual electrode layers, wherein each of the intrinsic semiconductor layers is located between one of the p-type semiconductor layers and one of the n-type semi-conductor layers, thereby forming at least two individual PIN structures, wherein each of the PIN structures is located between at least two of the electrode layers, thereby forming at least two photodiodes, wherein each of the two photodiodes has at least one longitudinal sensor region, wherein the longitudinal optical sensor is designed to generate at least two longitudinal sensor signals in a manner dependent on an illumination of the longitudinal sensor region by the light beam, wherein the longitudinal sensor signals, given the same total power of the illumination, are dependent on a beam cross-section of the light beam in the longitudinal sensor region; and
evaluating the longitudinal sensor signals by using at least one evaluation device and generating at least one item of information on a longitudinal position of the object.

### Embodiment 37

A tracking system for tracking a position of at least one movable object, the tracking system comprising at least one detector system according to any one of the preceding embodiments referring to a detector system, the tracking system further comprising at least one track controller, wherein the track controller is adapted to track a series of positions of the object at specific points in time.

### Embodiment 38

A scanning system for determining at least one position of at least one object, the scanning system comprising at least one detector according to any of the preceding embodiments referring to a detector, the scanning system further comprising at least one illumination source adapted to emit at least one light beam configured for an illumination of at least one dot located at at least one surface of the at least one object, wherein the scanning system is designed to generate at least one item of information about the distance between the at least one dot and the scanning system by using the at least one detector.

### Embodiment 39

A camera for imaging at least one object, the camera comprising at least one detector according to any one of the preceding embodiments referring to a detector.

### Embodiment 40

A use of the detector according to any one of the preceding embodiments relating to a detector, for a purpose of use, selected from the group consisting of: a position measurement in traffic technology; an entertainment application; a security application; a surveillance application; a safety application; a human-machine interface application; a tracking application; a photography application; a use in combination with at least one time-of-flight detector; a use in combination with a structured light source; a use in combination with a stereo camera; a machine vision application; a robotics application; a quality control application; a manufacturing application; a use in combination with a structured illumination source; a use in combination with a stereo camera.

### BRIEF DESCRIPTION OF THE FIGURES

Further optional details and features of the invention are evident from the description of preferred exemplary embodiments which follows in conjunction with the dependent claims. In this context, the particular features may be implemented alone or with several in combination. The invention is not restricted to the exemplary embodiments. The exemplary embodiments are shown schematically in the figures. Identical reference numerals in the individual figures refer to identical elements or elements with identical function, or elements which correspond to one another with regard to their functions.

Specifically, in the figures:

FIG. 1 shows an exemplary embodiment of a longitudinal optical sensor and a transversal optical sensor of a detector according to the present invention, in a sectional view;

FIG. 2 shows an exemplary embodiment of the detector according to the present invention;

FIG. 3 shows an exemplary embodiment of the longitudinal optical sensor and the transversal optical sensor of the detector according to the present invention;

FIG. 4 shows an exemplary embodiment of the longitudinal optical sensor of the detector according to the present invention; and

FIG. 5 shows an exemplary embodiment of a detector, a detector system, a human-machine interface, an entertainment device and a tracking system according to the present invention.

### EXEMPLARY EMBODIMENTS

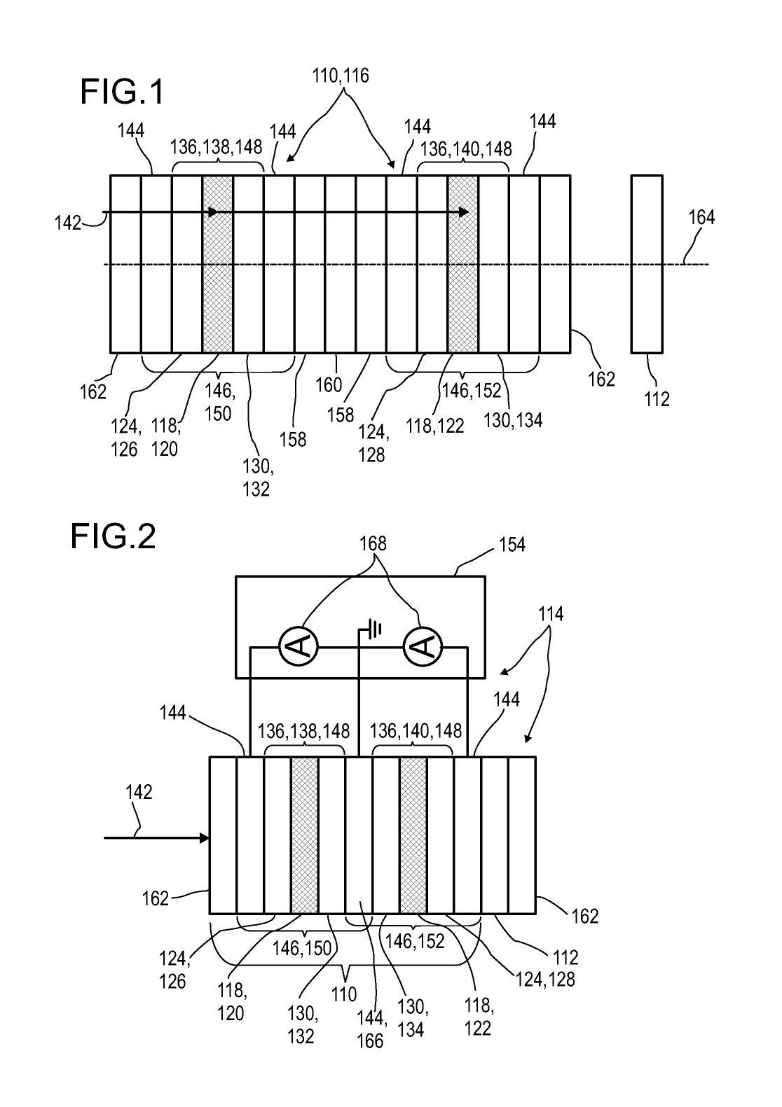

FIG. 1 shows, in a highly schematic illustration, an exemplary embodiment of a longitudinal optical sensor 110 and a transversal optical sensor 112 of a detector 114 according to the present invention. The longitudinal optical sensor 110 has a layer setup. The longitudinal optical sensor 110 may comprise at least two intrinsic semiconductor layers 118, for example a first intrinsic semiconductor layer 120 and a second intrinsic semiconductor layer 122. The longitudinal optical sensor 110 comprises at least two p-type semiconductor layers 124, for example, a first p-type semiconductor layer 126 and a second p-type semiconductor layer 128. The longitudinal optical sensor 110 comprises at least two n-type semiconductor layers 130, for example, a first n-type semiconductor layer 132 and a second n-type semiconductor layer 134. Each of the intrinsic semiconductor layers 118 may be located between one of the p-type semiconductor layers 124 and one of the n-type semiconductor layers 130, thereby forming at least two individual PIN structures 136, for example, a first PIN structure 138 and s second PIN structure 140.

The intrinsic semiconductor layers 118, the p-type semiconductor layer 124 and the n-type semiconductor layers 130 may comprise one or more of amorphous silicon, also abbreviated as “a-Si”, an alloy comprising amorphous silicon (a-Si), an alloy comprising amorphous silicon (a-Si), microcrystalline silicon (μc-Si), germanium (Ge), copper indium sulfide (CIS), copper indium gallium selenide (CIGS), copper zinc tin sulfide (CZTS), copper zinc tin selenide (CZTSe), copper-zinc-tin sulfur-selenium chalcogenide (CZTSSe), cadmium telluride (CdTe), mercury cadmium telluride (HgCdTe), indium arsenide (InAs), indium gallium arsenide (InGaAs), indium antimonide (InSb), an organic-inorganic halide perovskite, and solid solutions and/or doped variants thereof. The alloy comprising amorphous silicon may be an amorphous alloy comprising silicon and carbon or an amorphous alloy comprising silicon and germanium. The amorphous silicon may be passivated by using hydrogen, by which application a number of dangling bonds within the amorphous silicon may be reduced by several orders of magnitude. As a result, hydrogenated amorphous silicon, usually abbreviated to “a-Si:H”, may exhibit a low amount of defects, thus, allow using it for optical devices. The p-type semiconductor layers 124, the intrinsic semiconductor layers 118 and the n-type semiconductor layers 130 may be based on a-Si:H. The thickness of the intrinsic semiconductor layers 118 may be from 100 nm to 300 nm, in particular from 150 nm to 200 nm.

The longitudinal optical sensor 110 may be at least partially transparent, in particular transparent or semitransparent. The layer setup 116 may be adapted to be traversed by the incident light beam 142 in an order in which the layers are arranged within the layer setup 116. Each of the layers in the layer setup 116 may be at least partially transparent or translucent. Thus, the intrinsic semiconductor layer 118 may have a thickness as small as possible. In particular, the intrinsic semiconductor layers 118 may be thin film layers, with a thickness from 100 nm to 300 nm, in particular from 150 nm to 200 nm. The thickness of the intrinsic semiconductor layers 118 may be chosen similar to layer thickness as used in high performance tandem cells. Thus, using thin intrinsic semiconductor layers 118 may allow manufacturing at least partially transparent longitudinal optical sensors 110.

The longitudinal optical sensor 110 comprises at least three individual electrode layers 144. In the embodiment shown in FIG. 1, the longitudinal optical sensor 110 comprises four electrode layers 144. The electrode layers 144 may comprise electrically conducting material. The electrode layers 144 may be at least partially transparent. The electrode layers may comprise transparent conductive oxide (TCO), in particular one or more of indium tin oxide (ITO), zinc oxide (ZnO), Fluorine-doped tin oxide (FTO), aluminum-doped zinc oxide (AZO), antimony tin oxide (ATO). Each of the PIN structures 136 is located between at least two of the electrode layers 144, thereby forming at least two photodiodes 146.

Each of the two photodiodes 146 has at least one longitudinal sensor region 148, wherein the longitudinal optical sensor 110 is designed to generate at least two longitudinal sensor signals in a manner dependent on an illumination of the longitudinal sensor region 148 by the light beam 142, wherein the longitudinal sensor signals, given the same total power of the illumination, are dependent on a beam cross-section of the light beam 142 in the longitudinal sensor region 148. Each of the photodiodes 146 may be configured to be addressed individually. Each of the electrode layers 144 may be connectable and separately addressable. Hence, a photocurrent generated by one of the photodiodes 146 may be determined separately from a photocurrent generated by another photodiode 146. A first photodiode 150 may be designed to generate at least a first longitudinal sensor signal, and a second photodiode 152 may be designed to generate at least a second longitudinal sensor signal. The detector 114 comprises at least one evaluation device 154, wherein the evaluation device 154 is configured to determine at least one longitudinal coordinate of the object 156 by evaluating the longitudinal sensor signals. As outlined above, the longitudinal coordinate z may be also derived, in particular by implementing the FiP effect explained in further detail in WO 2012/110924 A1 and/or in WO 2014/097181 A1. For this purpose, the at least one longitudinal sensor signal as provided by the FIP sensor is evaluated by using the evaluation device 154 and determining, therefrom, at least one longitudinal coordinate z of the object 156. The evaluation device 154 may be adapted to determine the first longitudinal optical sensor signal and the second longitudinal sensor signal simultaneously. The photodiodes 146 may be arranged such that the first longitudinal optical sensor signal may be independent from the second longitudinal optical sensor signal. Thus, it may be possible to determine the longitudinal coordinate of the object 156 unambiguously.

Two adjacent electrode layers 144 having the same polarity may be separated from each other by an insulating layer 158. The insulating layer 158 may be at least partially transparent or at least partially translucent. The insulating layer 158 may comprise a layer of one of glass, quartz, or a transparent organic polymer. The longitudinal optical sensor may comprise at least one spacer layer 160, in particular an optical spacer layer, wherein the spacer layer 160 is designed to separate the first photodiode 150 and a second photodiode 152. The spacer layer 160 may comprise a layer of one of glass, quartz, or a transparent organic polymer. Using an optical spacer layer 160 and/or at least one insulating layer 158 of an appropriate thickness may allow to set a distance between two PIN structures 136.

The layer setup 116 may further comprise at least one substrate layer 162 comprising a layer of an opaque or transparent substrate, for example glass or a transparent or intransparent organic polymer. In the embodiment shown in FIG. 1, the layer setup may comprise two at least partially transparent substrate layers 162

The detector 114 may further comprise at least one transversal optical sensor 112. The transversal optical sensor 112 may be designed as at least one imaging device and/or at least one PSD. The longitudinal optical sensor 110 and the imaging device and/or the PSD may be arranged on a common optical axis 164. The longitudinal optical sensor 110 and the transversal optical sensor 112 may be arranged in a stack, as separated devices. The transversal optical sensor 112 may be situated in a direction of light propagating from the object 156 to the detector 114 behind the transparent longitudinal optical sensor 110. In this case, the PSD may be a standard quadrant detector or an opaque silicon based PSD. Additionally or alternatively, the imaging device may be based on intransparent inorganic materials, such as known CCD sensors and/or CMOS sensors.

FIG. 2 shows, highly schematic, an exemplary embodiment of the detector 114 according to the present invention. With respect to description of devices and elements, reference can be made to the description of FIG. 1, differences or specific features will be described in the following. Two adjacent PIN structures 136 may be separated by at least one electrode layer. Two adjacent PIN structures 136 may share one of the electrode layers 144 as a common electrode layer 166. Such an arrangement may allow miniaturizing the detector. As outlined above, each of the photodiodes 146 may be configured to be addressed individually. Each of the electrode layers 144 may be connectable and separately addressable. In the embodiment depicted in FIG. 2, each of the two individual electrode layers 144 may be addressed by at least one current measuring device 168, in particular to at least one ampere meter, by at least one connector 170 in order to determine the first longitudinal sensor signal and the second longitudinal sensor signal independently. Hence, a photocurrent generated by one of the photodiodes 146 may be determined separately from a photocurrent generated by another photodiode 146. Thus, it may be possible to determine the longitudinal coordinate of the object 156 unambiguously.

In FIG. 2, the transversal optical sensor 112 and the longitudinal optical sensor 110 may be arranged in a monolithic device. The layer setup 116 may further comprise at least one layer adapted to act as a transversal optical sensor 112. The layer adapted to act as a transversal optical sensor 112 may be intransparent and may be arranged as the last layer in the layer setup 116 to be traversed by the incident light beam 142. Thus, the layer adapted to act as transversal optical sensor 112 may be opaque. The layer setup 116 may comprise at least one substrate layer 162, in particular comprising glass or opaque substrate, behind the transversal optical sensor 112. The layer setup 116 may comprise a further substrate layer 162, in particular a first layer of the layer setup 116 may be designed as substrate layer 162.

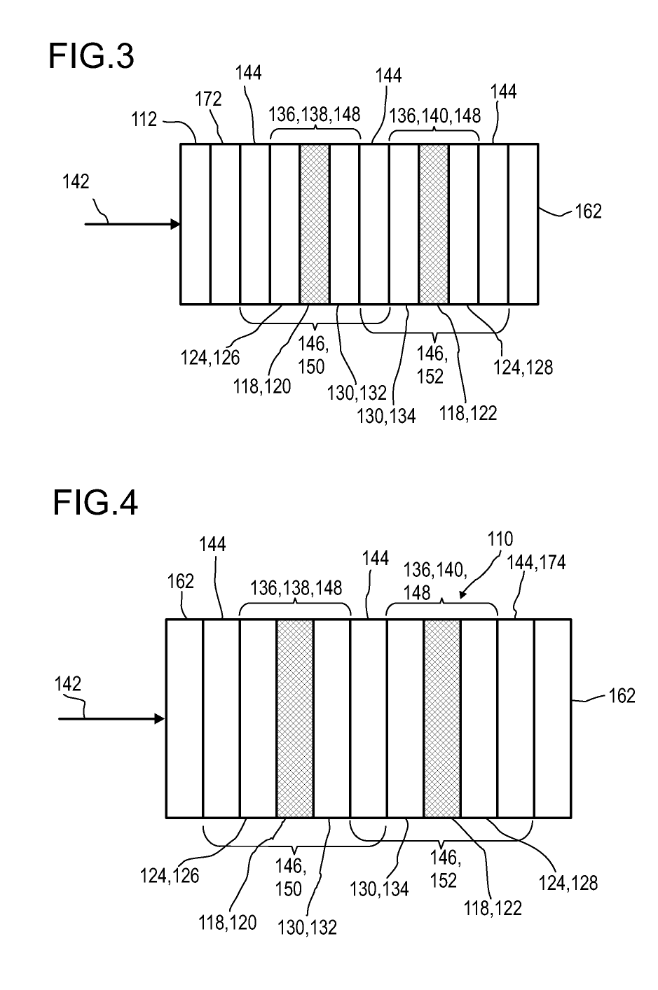

FIG. 3 shows, highly schematic, an exemplary embodiment of the longitudinal optical sensor 110 and the transversal optical sensor 112. With respect to description of devices and elements, reference can be made to the description of FIGS. 1 and 2, differences or specific features will be described in the following. The layer adapted to act as transversal optical sensor 112 may be arranged as first layer in the layer setup 116 to be traversed by the incident light beam 142. The layer adapted to act as a transversal optical sensor 112 maybe at least partially transparent or translucent. For example, the transversal optical sensor 112 may be a PSD. The PSD may be at least partially transparent or semitransparent. A semitransparent PSD may be realized by using a metal insulator semiconductor (MIS) layout. The PSD may comprise at least one photo sensitive area, in particular a photo-active layer. The photo-active layer may be silicon based, in particular the photoactive layer of the PSD may comprise one or more of a-Si:H, a-SiGe:H, a-Se:H and μc-Si:H. The PSD may have a PIN structure. An intrinsic semiconductor layer of the PIN structure may be designed such that the PSD is at least partially transparent or semitransparent. In particular, a thickness of the intrinsic semiconductor layer may be from 100 nm to 2000 nm, in particular from 400 to 700 nm. The PSD may comprise at least four electrodes. The electrodes may be designed as extended parallel electrodes. The electrodes may comprise sputtered or atmospheric pressure chemical vapour deposited transparent conductive oxide (TCO). In particular, the electrodes may comprise a low-conductivity layer, in particular indium tin oxide (ITO) or fluorine doped tin oxide (FTO). The PSD may have a square or quadrant detector. For example, the PSD may be a tetra-lateral type PSD having the four electrodes arranged along each side of the square or quadrant on a surface of the PSD. For example, the PSD may be a duo-lateral type PSD having a pair of the four electrodes on each of two surfaces of the PSD, in particular a pair of electrodes on a front surface and a pair of electrodes on a back surface of the PSD, wherein the pairs of electrodes are arranged at right angles.

The layer setup 116 may further comprise at least one at least partially transparent insulating layer 172, in particular comprising one or more of glass, quartz or a transparent organic polymer, positioned behind the transversal optical sensor 112.

FIG. 4 shows, highly schematic, an exemplary embodiment of the longitudinal optical sensor 110. With respect to description of devices and elements, reference can be made to the description of FIGS. 1 to 3, differences or specific features will be described in the following. In this embodiment, the longitudinal optical sensor 110 may be a stand-alone device which can be combined with further devices, e.g. with at least one transversal optical sensor. The electrode layers 144 may be at least partially transparent. The electrode layers may comprise transparent conductive oxide (TCO), in particular one or more of indium tin oxide (ITO), zinc oxide (ZnO), Fluorine-doped tin oxide (FTO), aluminum-doped zinc oxide (AZO), antimony tin oxide (ATO).

At least one of the electrode layers 144 may be designed as reflective electrode 174. The reflective electrode 174 may be arranged as last layer of the layer setup 116 to be traversed by the incident light beam 142. The layer setup 116 may comprise in a direction of propagation of the light beam in addition to the reflective electrode at least one additional layer, in particular the substrate layer 162, which may not be traversed by the incident light beam. Thus, the substrate layer 162 may be opaque. However, embodiments are feasible, wherein all electrode layers 144 and both substrate layers 162 are at least partially transparent.

The longitudinal optical sensor 110 may be adapted to operate as FiP-device and at the same time as PSD. The longitudinal optical sensor 110 may be adapted to operate as a FiP-device and at the same time as PSD adapted for one-dimensional position sensing. For example, the longitudinal optical sensor 110 may comprise two cells, wherein each cell may comprise at least one PIN structure 136 and/or PN structure and two electrode layers 144. The two cells may share one of the electrode layers 144 such that the two cells have a common electrode layer. The common electrode layer may be designed as common anode. Each cell may be configured as FiP-device and at the same time as 1D-PSD. Each cell may comprise a semi-transparent thin-film detector such as one or more of an a-Si:H thin-film detector, a μc-Si:H, CdTe, a nanoparticle thin-film detector or an organic thin-film detector. The 1D-PSD may comprise at least two electrodes on the surface of the PSD. The two electrodes on the surface of the 1D-PSD may be designed as cathodes. The two cells may be rotated by 90° to each other such that one cell is adapted to determine the transversal coordinate x and the other cell the transversal coordinate y. Electrode contacts of the anode and cathode electrode layers may be arranged on two sides of a cell opposite to each other.

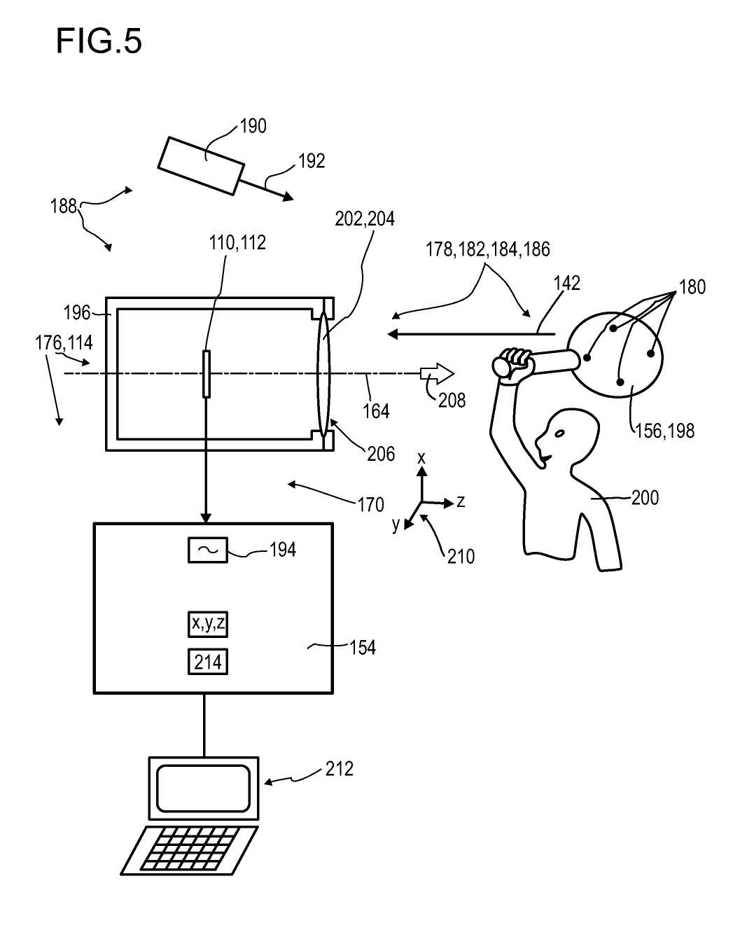

FIG. 5 shows, in a highly schematic illustration, an exemplary embodiment of a detector 114, comprising at least one longitudinal optical sensor 110 and at least one transversal optical sensor 112 arranged in a monolithic device. Within this regard it may be mentioned that the longitudinal sensors 110 and the transversal optical sensors 112 as presented in FIGS. 1 to 4, respectively, comprise an arrangement which is particularly suited for this purpose. The longitudinal optical sensor 110 is a FiP sensor which functions according to the above-described FiP effect. The detector 114 specifically may be embodied as a camera 176 or may be part of a camera 176. The camera 176 may be made for imaging, specifically for 3D imaging, and may be made for acquiring standstill images and/or image sequences such as digital video clips. Other embodiments are feasible.

FIG. 5 further shows an embodiment of a detector system 178, which, besides the at least one detector 114, comprises one or more beacon devices 160, which, in this exemplary embodiment, are attached and/or integrated into an object 156, the position of which shall be detected by using the detector 114. FIG. 5 further shows an exemplary embodiment of a human-machine interface 182, which comprises the at least one detector system 178, and, further, an entertainment device 184, which comprises the human-machine interface 182. The figure further shows an embodiment of a tracking system 186 for tracking a position of the object 156, which comprises the detector system 178. The components of the devices and systems shall be explained in further detail in the following.

FIG. 5 further shows an exemplary embodiment of a scanning system 188 for determining at least one position of the at least one object 156. The scanning system 188 comprises the at least one detector 114 and, further, at least one illumination source 190 adapted to emit at least one light beam 192 configured for an illumination of at least one dot (e.g. a dot located on one or more of the positions of the beacon devices 180) located at at least one surface of the at least one object 156. The scanning system 188 is designed to generate at least one item of information about the distance between the at least one dot and the scanning system 188, specifically the detector 114, by using the at least one detector 114.

As outlined above, the detector 114 may comprise, besides the one or more transversal optical sensors 112 and one or more longitudinal optical sensors 110, at least one evaluation device 154, having e.g. optionally at least one modulation device 194, as symbolically depicted in FIG. 5. Herein, the modulation device 194 may be employed for modulating the illumination, such as that the longitudinal sensor signal and/or the transversal sensor signal is dependent on a modulation frequency of a modulation of the illumination. The components of the evaluation device 154 may fully or partially be integrated into one or all of or even each of the optical sensors 110, 112 or may fully or partially be embodied as separate components independent from the optical sensors 110, 112.

Besides the above-mentioned possibility of fully or partially combining two or more components, one or more of one or more optical sensors 110, 112 and one or more of the components of the evaluation device 154 may be interconnected by one or more connectors 170 and/or one or more interfaces, as symbolically depicted in FIG. 5. Further, the optional at least one connector 170 may comprise one or more drivers and/or one or more devices for modifying or preprocessing sensor signals. Further, instead of using the at least one optional connector 170, the evaluation device 154 may fully or partially be integrated into the optical sensors 110, 112 and/or into a housing 196 of the detector 114. Additionally or alternatively, the evaluation device 154 may fully or partially be designed as a separate device.

In this exemplary embodiment, the object 156, the position of which may be detected, may be designed as an article of sports equipment and/or may form a control element or a control device 198, the position of which may be manipulated by a user 200. As an example, the object 156 may be or may comprise a bat, a racket, a club or any other article of sports equipment and/or fake sports equipment. Other types of objects 156 are possible. Further, the user 200 himself or herself may be considered as the object 156, the position of which shall be detected.

As outlined above, the detector 114 comprises one or more optical sensors 110, 112. The optical sensors 110,112 may be located inside the housing 196 of the detector 114. Further, at least one transfer device 202 may be comprised, such as one or more optical systems, preferably comprising one or more lenses 204.

An opening 206 inside the housing 196, which, preferably, is located concentrically with regard to an optical axis 164 of the detector 114, preferably defines a direction of view 208 of the detector 114. A coordinate system 210 may be defined, in which a direction parallel or antiparallel to the optical axis 164 is defined as a longitudinal direction, whereas directions perpendicular to the optical axis 164 may be defined as transversal directions. In the coordinate system 210, symbolically depicted in FIG. 5, a longitudinal direction is denoted by z, and transversal directions are denoted by x and y, respectively. Other types of coordinate systems 210 are feasible.

The one or more light beams 142 are propagating from the object 156 and/or from and/or one or more of the beacon devices 180 towards the detector 114. The detector 114 is adapted for determining a position of the at least one object 156. For this purpose, as explained above in the context of FIGS. 1-4, the evaluation device 154 is configured to evaluate sensor signals provided by the one or more optical sensors 110, 112. The detector 114 is adapted to determine a position of the object 156, and the optical sensors 110, 112 are adapted to detect the light beam 142 propagating from the object 156 towards the detector 114, specifically from one or more of the beacon devices 180. For example, the light beam 142 may be impinge directly and/or after being modified by the transfer device 202, such as being focused by the lens 204, on the longitudinal optical sensor 110 or the transversal optical sensor 112.

As outlined above, the determination of a position of the object 156 and/or a part thereof by using the detector 114 may be used for providing a human-machine interface 182, in order to provide at least one item of information to a machine 212. In the embodiment schematically depicted in FIG. 5, the machine 212 may be a computer and/or may comprise a computer. Other embodiments are feasible. The evaluation device 154 even may fully or partially be integrated into the machine 212, such as into the computer.

As outlined above, FIG. 5 also depicts an example of a tracking system 186, configured for tracking the position of the at least one object 156. The tracking system 186 comprises the detector 114 and at least one track controller 214. The track controller 214 may be adapted to track a series of positions of the object 156 at specific points in time. The track controller 214 may be an independent device and/or may fully or partially form part of the computer of the machine 212.

Similarly, as outlined above, the human-machine interface 182 may form part of an entertainment device 184. The machine 212, specifically the computer, may also form part of the entertainment device 184. Thus, by means of the user 200 functioning as the object 156 and/or by means of the user 200 handling a control device 198 functioning as the object 156, the user 200 may input at least one item of information, such as at least one control command, into the computer, thereby varying the entertainment function, such as controlling the course of a computer game.

### LIST OF REFERENCE NUMBERS

110 longitudinal optical sensor
112 transversal optical sensor
114 detector
116 layer setup
118 intrinsic semiconductor layer
120 first intrinsic semiconductor layer
122 second intrinsic semiconductor layer
124 p-type semiconductor layer
126 first p-type semiconductor layer
128 second p-type semiconductor layer
130 n-type semiconductor layer
132 first n-type semiconductor layer
134 second n-type semiconductor layer
136 PIN structure
138 first PIN structure
140 second PIN structure
142 light beam
144 electrode layers
146 photodiodes
148 longitudinal sensor region
150 first photodiode
152 second photodiode
154 evaluation device
156 object
158 insulating layer
160 spacer layer
162 substrate layer
164 optical axis
166 common electrode layer
168 current measuring device
170 connector
172 insulating layer
174 reflective electrode
176 camera
178 detector system
180 beacon device
182 human-machine interface
184 entertainment device
186 trading system
188 scanning system
190 illumination source
192 light beam
194 modulation device
196 housing
198 control device
200 User
202 transfer device
204 Lens
206 opening
208 direction of view
210 coordinate system
212 machine
214 track controller

1: A detector for determining a position of at least one object, the detector comprising:
a longitudinal optical sensor for determining a longitudinal position of at least one light beam traveling from the at least one object to the detector, the longitudinal optical sensor having a layer setup, wherein the longitudinal optical sensor comprises at least two p-type semiconductor layers, at least two n-type semiconductor layers, and at least three individual electrode layers, wherein the at least two p-type semiconductor layers and the at least two n-type semiconductor layers form at least two individual PN structures, wherein each of the at least two individual PN structures is located between at least two of the at least three electrode layers, thereby forming at least two photodiodes,
wherein each of the at least two photodiodes has at least one longitudinal sensor region, wherein the longitudinal optical sensor generates at least two longitudinal sensor signals in a manner dependent on an illumination of the at least one longitudinal sensor region by the at least one light beam, and wherein the at least two longitudinal sensor signals, given the same total power of the illumination, are dependent on a beam cross-section of the at least one light beam in the at least one longitudinal sensor regions; and
an evaluation device for determining at least one longitudinal coordinate of the at least one object by evaluating the at least two longitudinal sensor signals.

2: The detector of claim 1, wherein the longitudinal optical sensor comprises an intrinsic semiconductor layer, and wherein the intrinsic semiconductor layer is located between one of the at least two p-type semiconductor layers and one of the at least two n-type semiconductor layers, thereby forming at least one PIN structure.

3: The detector of claim 1, wherein the longitudinal optical sensor comprises at least two intrinsic semiconductor layers, and wherein each of the at least two intrinsic semiconductor layers is located between one of the at least two p-type semiconductor layers and one of the at least two n-type semiconductor layers, thereby forming at least two individual PIN structures.

4: The detector of claim 2, wherein one or more of the intrinsic semiconductor layer, the at least two p-type semiconductor layers and the at least two n-type semiconductor layers comprise at least one selected from the group consisting of amorphous silicon, an alloy comprising amorphous silicon, microcrystalline silicon, germanium, copper indium sulfide, copper indium gallium selenide, copper zinc tin sulfide, copper zinc tin selenide, copper-zinc-tin sulfur-selenium chalcogenide, cadmium telluride, mercury cadmium telluride, indium arsenide, indium gallium arsenide, indium antimonide, an organic-inorganic halide perovskite, and solid solutions and/or doped variants thereof.

5: The detector of claim 4, wherein one or more of the intrinsic semiconductor layer, the at least two p-type semiconductor layers and the at least two n-type semiconductor layers comprise the alloy comprising amorphous silicon, and
the alloy comprising amorphous silicon is an amorphous alloy comprising silicon and carbon or an amorphous alloy comprising silicon and germanium.

6: The detector of claim 4, wherein one or more of the intrinsic semiconductor layer, the at least two p-type semiconductor layers and the at least two n-type semiconductor layers comprise the amorphous silicon, and
the amorphous silicon is passivated with hydrogen.

7: The detector of claim 1, wherein the longitudinal optical sensor comprises an intrinsic semiconductor layer; and
the intrinsic semiconductor layers have a thickness of from 100 nm to 300 nm.

8: The detector of claim 1, wherein the longitudinal optical sensor is at least partially transparent.

9. (canceled)

10: The detector of claim 1, wherein each of the at least two p-type semiconductor layers, the at least two n-type semiconductor layers, and the at least three individual electrode layers in the layer setup is at least partially transparent or translucent.

11. (canceled)

12: The detector of claim 1, wherein two adjacent PN structures of the at least two individual PN structures share one of the at least three electrode layers as a common electrode layer.

13: The detector of claim 1, wherein two adjacent layers of the at least three electrode layers having the same polarity are separated from each other by an insulating layer, and
wherein the insulating layer comprises a layer of one of glass, quartz, or a transparent organic polymer.

14. (canceled)

15: The detector of claim 1, wherein each of the at least two photodiodes is addressed individually.

16: The detector of claim 1, wherein the at least two photodiode comprises a first photodiode and a second photodiode;
the first photodiode generates at least a first longitudinal sensor signal
the second photodiode generates at least a second longitudinal sensor signal, and
the evaluation device determines the first longitudinal optical sensor signal and the second longitudinal sensor signal simultaneously.

17: The detector of claim 1, wherein the at least three electrode layers comprise electrically conductive material,
wherein the at least three electrode layers are at least partially transparent, and
wherein the at least three electrode layers comprise transparent conductive oxide.

18: The detector of claim 1, wherein the longitudinal optical sensor comprises a spacer layer, and wherein the spacer layer separates a first photodiode and a second photodiode.

19: The detector of claim 1, wherein the detector further comprises a transversal optical sensor for determining at least one transversal position of the at least one light beam traveling from the at least one object to the detector,
wherein the transversal optical sensor generates at least one transversal sensor signal, and
wherein the evaluation device further determines at least one transversal coordinate of the at least one object by evaluating the at least one transversal sensor signal.

20: The detector of claim 1, wherein the layer setup comprises at least one layer acting as a transversal optical sensor, and
the longitudinal optical sensor and the transversal optical sensor are arranged in a monolithic device.

21. (canceled)

22: The detector of claim 20, wherein the layer acting as a transversal optical sensor is intransparent and arranged as a last layer in the layer setup to be traversed by the at least one light beam, which is an incident light beam.

23: The detector of claim 20, wherein the layer acting as a transversal optical sensor is at least partially transparent or translucent.

24: The detector of claim 20, wherein the layer acting as transversal optical sensor is arranged as a first layer in the layer setup to be traversed by the at least one light beam, which is an incident light beam.

25-29. (canceled)

30: A method for determining a position of at least one object with the detector of claim 1, the method comprising:
generating the at least two longitudinal sensor signals with the longitudinal optical sensor and
evaluating the at least two longitudinal sensor signals with the evaluation device and generating at least one item of information on a longitudinal position of the at least one object.

31-34. (canceled)
